(19) United States
(12) Patent Application Publication
(10) Pub. No.: US 2025/0335656 A1
(43) Pub. Date: Oct. 30, 2025

(54) Systems and methods for automatically identifying design element groups

(71) Applicant: Canva Pty Ltd, Surry Hills (AU)

(72) Inventors: Xin LIANG, Melbourne (AU); Joel NOTHMAN, Dover Heights (AU)

(73) Assignee: Canva Pty Ltd, Surry Hills (AU)

(21) Appl. No.: 19/095,113

(22) Filed: Mar. 31, 2025

(30) Foreign Application Priority Data
Apr. 24, 2024 (AU) 2024202684

(51) Int. Cl. G06F 30/20; G06F 9/451

(52) U.S. Cl. CPC G06F 30/20; G06F 9/451

(57) ABSTRACT

Described herein is a computer implemented method that includes accessing input design data in respect of an input design, processing the input design data to generate a raster design that corresponds to the input design, and processing the raster design to identify a first object in the raster design, wherein the first object corresponds to a first element group. The method further includes determining that first and second design elements of the input design are members of the first element group based on positions of the first and second design elements in the input design and a position of the first object in the raster design.

### CROSS-REFERENCE TO RELATED APPLICATION

This application is a U.S. Non-Provisional Application that claims priority to Australian Patent Application No. 2024202684, filed Apr. 24, 2024, which is hereby incorporated by reference in its entirety.

### TECHNICAL FIELD

Aspects of the present disclosure are directed to systems and methods for automatically identifying design element groups.

### BACKGROUND

Various computer applications for creating and publishing graphic designs exist. Generally speaking, such applications allow users to create a design by, for example, creating a page, adding design elements to that page, and editing design elements (e.g. by moving, resizing, recolouring, and/or performing other edit operations).

In certain scenarios, a user of such an application may wish to group design elements together. Once two or more elements have been added to a group, the group can be manipulated as a single element.

Consider, for example a user who has added two design elements to a page. If the user wishes to move both of those design elements they can move both design elements individually. Alternatively, the user can create a group including the two design elements, in which case the group as a whole can be moved and doing so causes both member elements to be moved consistently.

Creating element groups can allow various operations to be more conveniently performed. For example, if a user wishes to make a same position change to multiple design elements (e.g. to move each element to the right by x pixels), many design tools will enable this to be done by either individually moving each design element (e.g. by dragging from an initial location to a new location) or by grouping the design elements and moving the group as a single entity.

Furthermore, the manner in which design elements are grouped may impact how certain operations are performed. One example of this is reflowing the elements of a design which may, for example, be performed if the aspect ratio (or size) of a design is changed. This may occur, for example, if a user manually changes the aspect ratio (or size). It may also occur if a design is converted from one format to another. In reflow operations, a design tool or other software application may be configured to automatically adjust the layout of the design's elements—e.g. their sizes and/or positions-based on the new aspect ratio (or size) of the design or viewport in which the design is displayed (e.g. if the design is a website that reflows when the viewport size changes). In such operations, the manner in which design elements are grouped can change the way that the design elements are adjusted and, ultimately, how successful or otherwise the automatic adjustment is.

Even where a design tool provides element grouping functionality, there are many situations where a user may not group design elements together even though grouping may be appropriate/beneficial. A user may not group design elements for various reasons. For example, a user may not group design elements because they do not know how to do so (or do not know that that creating element groups is an available feature). As another example, a user may not group design elements together because doing so is too time consuming. As a further example, a user may not group design elements because they are not aware that doing so may provide benefits in certain downstream operations (e.g. in reflowing design elements when a design is resized).

Background information described in this specification is background information known to the inventors. Reference to this information as background information is not an acknowledgment or suggestion that this background information is prior art or is common general knowledge to a person of ordinary skill in the art.

### SUMMARY

In one aspect, the present invention provides a computer implemented method including: accessing input design data in respect of an input design that includes a plurality of design elements; processing, by a computer processing unit, the input design data to generate a raster design that corresponds to the input design; processing the raster design to identify a first object in the raster design, wherein the first object corresponds to a first element group; determining members of the first element group, wherein determining the members of the first element group includes: determining that a first design element of the plurality of design elements is a member of the first element group based on a position of the first design element in the input design and a position of the first object in the raster design; and determining that a second design element of the plurality of design elements is a member of the first element group based on a position of the second design element in the input design and a position of the first object in the raster design; and generating a first element group record that includes an identifier of the first design element and an identifier of the second design element.

### BRIEF DESCRIPTION OF THE DRAWINGS

In the drawings:

FIG. 1 is a diagram depicting a networked environment in which various features of the present disclosure may be implemented.

FIG. 2 is a block diagram of a computer processing system configurable to perform various features of the present disclosure.

FIG. 3 depicts an example graphical user interface.

FIG. 4 is a flowchart depicting operations performed in a method for identifying design element groups.

FIG. 5 depicts an example design that includes various design elements.

FIG. 6 depicts design raster that corresponds to the design depicted in FIG. 5.

FIG. 7 is a flowchart depicting operations performed in a method for generating element groups based on identified objects.

FIG. 8 is a flowchart depicting operations performed in a method for generating an original training example.

FIG. 9 depicts an example user interface.

FIG. 10 is a flowchart depicting operations performed in a method for generating one or more synthetic training examples based on an existing training example.

FIG. 11 depicts generation of a new design based on a rotated design.

FIG. 12 depicts rotation of an element group.

FIG. 13 is a flowchart depicting operations performed in a method for generating a group transferred synthetic training example.

While the description is amenable to various modifications and alternative forms, specific embodiments are shown by way of example in the drawings and are described in detail. It should be understood, however, that the drawings and detailed description are not intended to limit the invention to the particular form disclosed. The intention is to cover all modifications, equivalents, and alternatives falling within the scope of the present invention as defined by the appended claims.

### DETAILED DESCRIPTION

In the following description numerous specific details are set forth in order to provide a thorough understanding of the present invention. It will be apparent, however, that the present invention may be practiced without these specific details. In some instances, well-known structures and devices are shown in block diagram form in order to avoid unnecessary obscuring.

The present disclosure is generally directed to systems and methods for automatically identifying design element groups. In certain embodiments, as well as automatically identifying design element groups the systems and methods operate to determine types of the design element groups that are identified.

In the present disclosure, design elements may be referred to as elements and design element groups may be referred to as element groups.

Once element groups have been identified (and, if performed, classified), the element group may be used for one or more specific purposes. For example, element groups that have been automatically identified may be presented to a user as suggested group and the user can then confirm, reject, or adjust the element members of the automatically identified element groups. As another example, identified element groups may be used to provide responsive layouts that adapt to a user viewing a design on a device with a different viewport (or page) size or aspect ratio. As a further example, an identified element group may assist in editing a design (e.g. as it can be manipulated or deleted from a design as a single entity) and/or in creating new designs (e.g. as it can be copied from one design and transferred to a new design as a single entity).

Also described herein are systems and methods for generating training data that can be used to train a machine learning model to identify (and, in certain embodiments, classify) design element groups.

Also described herein is a machine learning model that is trained to identify (and, in certain embodiments, classify) design element groups.

The techniques disclosed herein are described in the context of a digital design platform that is configured to facilitate various operations concerned with digital designs.

A digital design platform may take various forms. In the embodiments described herein the digital design platform is a client-server type platform (e.g. one or more client applications and one or more server applications that interoperate to perform the described techniques). The techniques described herein can, however, be performed (or be adapted to be performed) by a stand-alone digital design platform (e.g. an application or set of applications that run on a user's computer processing system and perform the techniques described herein without requiring server-side operations).

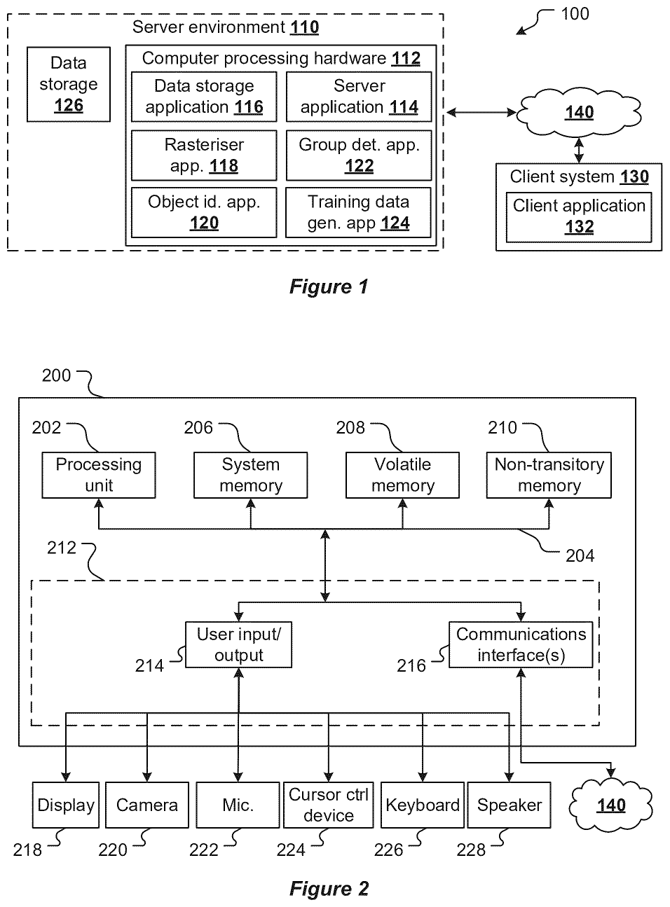

FIG. 1 is a diagram depicting a networked environment 100 in which various features of the present disclosure may be implemented.

Networked environment 100 includes a server environment 110 and a client system 130 which communicate via one or more communications networks 140 (e.g. the Internet).

Generally speaking, the server environment 110 includes computer processing hardware 112 (discussed below) on which applications that provide server-side functionality to client applications such as client application 132 (described below) execute.

In the present example, server environment 110 includes various applications that are executed by computer processing hardware 112: a server application 114 (which may also be referred to as a front end server application), a data storage application 116, a rasterizer application 118, an object identification application 120, a group determination application 122, and a training data generation application 124. Server environment 110 also includes one or more data storage devices 126.

In the present embodiment, the server application 114 executes to provide a client application endpoint that is accessible over communications network 140. Server application 114 may, for example, be a web server application that serves web browser client applications by receiving and responding (for example) to HTTP requests. As an alternative example, server application 114 may be an application server that is configured to serve native client applications by receiving and responding to specifically defined API calls received from those client applications. The server environment 110 may include one or more web server applications and/or one or more application server applications allowing it to interact with both web and native client applications.

Server application 114 (and/or other applications of server environment 110) may be configured to facilitate various functions related to digital designs. These functions may include, for example, design creation, editing, storage, retrieval, organisation, searching, viewing, sharing, publishing, and/or other functions related to digital designs. The server application 114 (and/or other applications) may also facilitate additional, related functions such as user account creation and management, user group creation and management, user and user group permission management, user authentication, and/or other server side functions.

In the present example, the data storage application 116 executes to receive and process requests to persistently store and retrieve data relevant to the operations performed by the server environment 110. Such requests may be received from the server application 114, other server environment applications, and/or (in some instances) directly from client applications such as 132. Data relevant to the operations performed/services provided by the server environment 110 may include, for example, user account data, user design data (i.e. data describing designs that have been created by users), template design data (e.g. templates that can be used by users to create designs), group identification training examples (e.g. data in respect of training examples that can be used to train a machine learning model to identify element groups); design element data (e.g. data in respect of stock design elements that users may add to designs), and/or other data relevant to the operation of the server environment 110.

The data storage application 116 may, for example, be a relational database management application or an alternative application for storing and retrieving data from data storage 126. Data storage 126 may be any appropriate data storage device (or set of devices), for example one or more non-transitory computer readable storage devices such as hard disks, solid state drives, tape drives, or alternative computer readable storage devices.

In server environment 110, server environment applications persistently stores data to data storage device 126 via the data storage application 116. In alternative implementations, however, server environment applications may be configured to directly interact with data storage devices such as 126 to store and retrieve data (in which case a separate data storage application may not be needed). Furthermore, while a single data storage application 116 and a single data storage device 126 is described and depicted, server environment 110 may include multiple data storage applications and/or multiple data storage devices. For example one data storage application 116 may be used for user account data, another for user design data, another for design element data and so forth. In this case, each data storage application may interface with one or more shared data storage devices and/or one or more dedicated data storage devices, and each data storage application may receive/respond to requests from various server-side and/or client-side applications (including, for example server application 114).

In the examples described herein, server environment 110 also includes a rasterizer application 118, an object identification application 120, a group determination application 122, and a training data generation application 124. The operation of these applications will be described below. In alternative embodiments, however, the operations performed by one or more of these applications may be performed by one or more alternative applications (including, in some instances, client-side applications). As one example, the operations of one these applications may be performed by a single monolithic application (e.g. server application 114 itself, or an alternative application).

As noted, the server environment 110 applications run on (or are executed by) computer processing hardware 112. Computer processing hardware 112 includes one or more computer processing systems. The precise number and nature of those systems will depend on the architecture of the server environment 110.

For example, in one implementation each server environment application may run on its own dedicated computer processing system. In an alternative implementation, two or more server environment applications may run on a common/shared computer processing system. In a further alternative implementation, server environment 110 may be a scalable environment in which application instances (and the computer processing hardware 112—i.e. the specific computer processing systems required to run those instances) are commissioned and decommissioned according to demand—e.g. in a public or private cloud-type system. In this case, server environment 110 may simultaneously run multiple instances of each application (on one or multiple computer processing systems) as required by client demand. Where server environment 110 is a scalable system it will include additional applications to those illustrated and described. As one example, the server environment 110 may include a load balancing application which operates to determine demand, direct client traffic to the appropriate server application instance 114 (where multiple server applications 114 have been commissioned), trigger the commissioning of additional server environment applications (and/or computer processing systems to run those applications) if required to meet the current demand, and/or trigger the decommissioning of server environment applications (and computer processing systems) if they are not functioning correctly and/or are not required for current demand.

Communication between the applications and computer processing systems of the server environment 110 may be by any appropriate means, for example direct communication or networked communication over one or more local area networks, wide area networks, and/or public networks (with a secure logical overlay, such as a VPN, if required).

Client system 130 hosts a client application 132 which, when executed by the client system 130, configures the client system 132 to provide client-side functionality/interact with server environment 110 (or, more specifically, the server application 114 and/or other applications provided by the server environment 110).

Client application 132 may be a general web browser application which accesses the server application 114 via an appropriate uniform resource locator (URL) and communicates with the server application 114 via general world-wide-web protocols (e.g. http, https, ftp). Alternatively, the client application 132 may be a native application programmed to communicate with server application 114 using defined application programming interface (API) calls and responses.

A given client system such as 130 may have more than one client application 132 installed and executing thereon. For example, a client system 130 may have a (or multiple) general web browser application(s) and a native client application.

The present disclosure describes various operations that are performed by applications of the server environment 110 and client application 132. In many instances, however, operations described as being performed by a particular application (e.g. server application 114) could be performed by (or in conjunction with) one or more alternative applications, and/or operations described as being performed by multiple separate applications could in some instances be performed by a single application.

While the embodiments described below make use of a client-server architecture, the techniques and processing described herein could be adapted to be executed in a stand-alone context—e.g. by an application (or set of applications) that run on a computer processing system and can perform all required functionality without need of a server environment or application.

The techniques and operations described herein are performed by one or more computer processing systems.

By way of example, client system 130 may be any computer processing system which is configured (or configurable) by hardware and/or software—e.g. client application 132—to offer client-side functionality. A client system 130 may be a desktop computer, laptop computer, tablet computing device, mobile/smart phone, or other appropriate computer processing system.

Similarly, the applications of server environment 110 are also executed by one or more computer processing systems (the computer processing hardware 112). Server environment computer processing systems will typically be server systems, though again may be any appropriate computer processing systems.

FIG. 2 provides a block diagram of a computer processing system 200 configurable to implement embodiments and/or features described herein. System 200 is a general purpose computer processing system. It will be appreciated that FIG. 2 does not illustrate all functional or physical components of a computer processing system. For example, no power supply or power supply interface has been depicted, however system 200 will either carry a power supply or be configured for connection to a power supply (or both). It will also be appreciated that different types of computer processing systems may have different hardware and architectures than the hardware and architecture that is depicted and described in the present example.

Computer processing system 200 includes at least one processing unit 202. The processing unit 202 may be a single computer processing device (e.g. a central processing unit, graphics processing unit, or other computational device), or may include a plurality of computer processing devices. In some instances, where a computer processing system 200 is described as performing an operation or function all processing required to perform that operation or function will be performed by processing unit 202. In other instances, processing required to perform that operation or function may also be performed by remote processing devices accessible to and useable by system 200.

Through a communications bus 204 the processing unit 202 is in data communication with a one or more machine readable storage (memory) devices which store computer readable instructions and/or data which are executed by the processing unit 202 to control operation of the processing system 200. In this example system 200 includes a system memory 206 (e.g. a BIOS), volatile memory 208 (e.g. random access memory such as one or more DRAM modules), and non-transitory memory 210 (e.g. one or more hard disk or solid state drives).

System 200 also includes one or more interfaces, indicated generally by 212, via which system 200 interfaces with various devices and/or networks. Generally speaking, other devices may be integral with system 200, or may be separate. Where a device is separate from system 200, the connection between the device and system 200 may be via wired or wireless hardware and communication protocols, and may be a direct or an indirect (e.g. networked) connection.

Generally speaking, and depending on the particular system in question, devices to which system 200 connects include one or more input devices to allow data to be input into/received by system 200 and one or more output device to allow data to be output by system 200.

By way of example, where system 200 is a personal computing device such as a desktop or laptop device, it may include a display 218 (which may be a touch screen display and as such operate as both an input and output device), a camera device 220, a microphone device 222 (which may be integrated with the camera device), a cursor control device 224 (e.g. a mouse, trackpad, or other cursor control device), a keyboard 226, and a speaker device 228.

As another example, where system 200 is a portable personal computing device such as a smart phone or tablet it may include a touchscreen display 218, a camera device 220, a microphone device 222, and a speaker device 228.

As another example, where system 200 is a server computing device it may be remotely operable from another computing device via a communication network. Such a server may not itself need/require further peripherals such as a display, keyboard, cursor control device etc. (though may nonetheless be connectable to such devices via appropriate ports).

System 200 also includes one or more communications interfaces 216 for communication with a network, such as network 140 of environment 100. Via the communications interface(s) 140, system 200 can communicate data to and receive data from networked systems and/or devices.

System 200 stores or has access to computer applications (which may also referred to as computer software or computer programs). Generally speaking, such applications include computer readable instructions and data which, when executed by the processing unit 202, configure system 200 to receive, process, and output data. Instructions and data can be stored on non-transitory machine readable medium such as 210 accessible to system 200. Instructions and data may be transmitted to/received by system 200 via a data signal in a transmission channel enabled (for example) by a wired or wireless network connection over an interface such as communications interface 216.

Typically, one application accessible to system 200 will be an operating system application. In addition, system 200 will store or have access to applications which, when executed by the processing unit 202, configure system 200 to perform various computer-implemented processing operations described herein. For example, and referring to the networked environment of FIG. 1 above, server environment 110 includes one or more systems which run a server application 114, a data storage application 116, a rasterizer application 118, an object identification application 120, a group determination application 122, and a training data generation application 124. Similarly, client system 130 runs a client application 132.

In some cases part or all of a given computer-implemented method will be performed by system 200 itself, while in other cases processing may be performed by other devices in data communication with system 200.

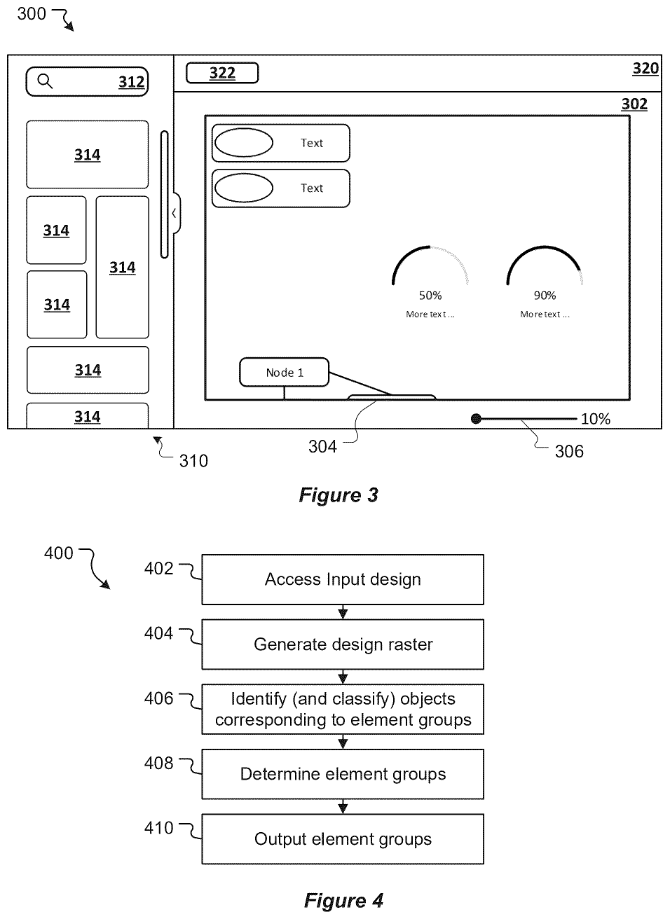

In certain embodiments, application 132 configures the client system 130 to provide an editor user interface (UI) 300. Generally speaking, UI 300 will allow a user to create, edit, and output designs. FIG. 3 provides a simplified and partial example of an editor UI. In this example the editor UI 300 is a graphical user interface (GUI).

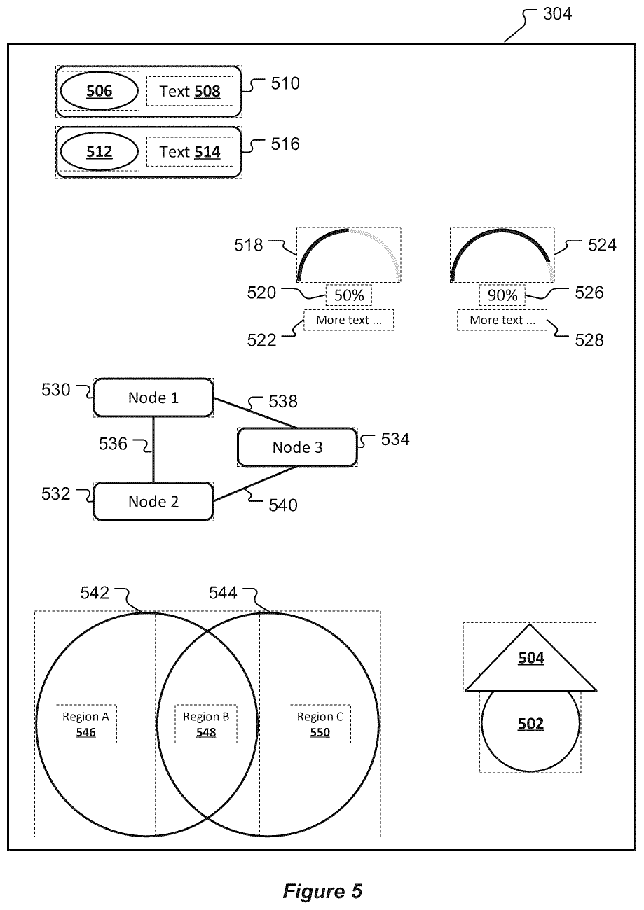

Editor UI 300 includes a design preview area 302. Design preview area 302 may, for example, be used to display a design 304 (or part thereof). Typically preview area 302 will be used to display a native format design that a user is working with. Preview area 302 may also be used to display a raster format design. Native and raster format designs are described further below. In this example, design 304 is displayed as a native format design and includes a number of design elements which are discussed further below with reference to FIG. 5. In this example the design preview area 302 includes a zoom control 306 (which a user can interact with to zoom into/out of the design that is currently displayed).

Example GUI 300 also includes search area 310. Search area 310 may be used, for example, to search for existing designs and/or other design assets that are available to a user to assist in creating designs. Different types of assets may be made available, for example design elements of various types (e.g. text elements, geometric shapes, vector graphics, raster images, videos, and/or other types of design elements), design templates, design styles (e.g. defined sets of colours, font types, and/or other design assets), and/or other assets that a user may use when creating a design.

In this example, search area 310 includes a search control 312 via which a user can submit search data (e.g. a string of characters). When a user submits a search (e.g. via search control 312) previews 316 (e.g. thumbnails or the like) of any search results may be displayed.

Depending on implementation, the previews 316 displayed in search area 310 (and the design assets corresponding to those previews) may be accessed from various locations. For example, the search functionality invoked by search control 312 may cause client application 132 to search for existing designs and/or design assets that are stored in locally accessible memory of the client system 130 (e.g. non-transitory memory such as 210 or other locally accessible memory), assets that are stored at a remote server (and accessed via a server application such as server application 114 running thereon), and/design or assets stored on other locally or remotely accessible devices.

Example GUI 300 also includes an additional controls area 320 that is used to display additional controls. The additional controls may include one or more: permanent controls (e.g. controls such as save, download, print, share, publish, and/or other controls that are frequently used/widely applicable and that application 132 is configured to permanently display); user configurable controls (which a user can select to add to or remove from area 320); and/or one or more adaptive controls (which application 132 may change depending, for example, on the type of design element that is currently selected/being interacted with by a user). For example, if a text element is selected, application 132 may display adaptive controls such as font style, type, size, position/justification, and/or other font related controls may be displayed. Alternatively, if a vector graphic element is selected, application 132 may display adaptive controls such as fill attributes, line attributes, transparency, and/or other vector graphic related controls may be displayed.

In the present example, and as discussed further below, UI 300 includes an identify design element groups control 322.

Once a design has been created, application 132 may provide various options for outputting that design. For example, application 132 may provide a user with options to output a design by one or more of: saving the design to local memory of client system 130 (e.g. non-transitory memory 210); saving the design to remotely accessible memory device; uploading the design to a server system (e.g. server environment 110); printing the design to a printer (local or networked); communicating the design to another user (e.g. by email, instant message, or other electronic communication channel); publishing the design to a social media platform or other service (e.g. by sending the design to a third party server system with appropriate API commands to publish the design); converting the design to a webpage and publishing that webpage; and/or by other output means.

With example GUI 300 in mind, a user may create and edit a design in various ways. For example, a user may interact with GUI 300 to create a new design from scratch, which causes a blank native format design (e.g. a page or canvas) to be displayed in preview area 302. Alternatively, a user may interact with GUI 300 to create a new design based on an existing design or template, in which case the existing design or template is displayed as a native format design in preview area 302. Once a native format design 304 is displayed in the preview area a user may add elements to it. For example, a user may search for elements using search control 312, select an element preview 314 that is displayed in response to the search, and add the element corresponding to a particular preview 314 to their design (e.g. by dragging and dropping the particular preview 314 onto the design 304). A user may also edit a design by editing elements of the design. For example, a user may move an element to change its position, rotate an element, resize an element and/or perform other size- or position-based edits. A user may also edit other attributes of a given element (with the editable attributes depending on the type of the element). By way of example, and depending on the type of element, a user may change one or more colours of an element, change the opacity of an element, change the text displayed by the element. Client application 132 (and the design platform in general) may make additional and/or alternative design editing operations available.

A design platform stores the data in respect of designs that have been (or are being) created and edited in what will be referred to as a native design data format (also referred to as a native format for convenience). Various schemas (or document object models) may be used for the native format. The following section provides a partial and simplified native format for designs for illustrative purposes. Alternative native design data formats are, however, possible, and the processing described herein can be adapted for alternative formats.

In the present context, data in respect of a particular design is stored in a design record. Generally speaking, a design record defines certain design-level attributes and includes element data that defines the design's elements.

In the present example, the format of each design record is a device independent format including a set of key-value pairs (e.g. a map or dictionary). To assist with understanding, a partial example of a design record format is as follows:

| Attribute | Example |
|---|---|
| Design ID | “designId”: “abc123” |
| Dimensions | “dimensions”: {“width”: 1080, “height”: 1080} |
| Design type | “type”: “poster” |
| Design name | “name”: “Test Doc 3” |
| Design owner | “owner”: 12ab34cd |
| Edit time | “edited”: <timestamp> |
| Background | “background”: {“mediaID”: “M12345”} |
| Element data | “elements”: [{element 1}, . . . {element n}] |

In this example, the design-level attributes include: a design identifier (which uniquely identifies the design); dimensions (e.g. a design width and height); a design type (e.g. an indicator of the type of the design, which may be used for searching and/or sorting purposes); a design name (e.g. a string defining a default or user specified name for the design); a design owner (e.g. an identifier of a user or group that owns or created the design); a most recent edit time (e.g. a timestamp indicating when the design was last edited); background (which identifies a background of the design, such as a particular image, graphic, colour, colour gradient, or other background); and element data (discussed below). Additional and/or alternative design-level attributes may be provided, such as attributes regarding creation date, design version, design permissions, and/or other design-level attributes.

In this example, a design's element data is a set (in this example an array) of element records. Each element record defines an element that has been added to the page. In this example, an element record's position in the elements array serves to identify the element and also determines the depth or z-index of the element (e.g. an element at array index n is positioned above an element at array index n−1 and below an element at array index n+1). Element depth may be alternatively handled, however, for example, by storing depth as an explicit element attribute.

Generally speaking, each element record defines an object that has been added to a design—e.g. by copying and pasting, importing from one or more asset libraries (e.g. libraries of images, animations, videos, etc.), drawing/creating using one or more design tools (e.g. a text tool, a line tool, a rectangle tool, an ellipse tool, a curve tool, a freehand tool, and/or other design tools), or by otherwise being added to a design.

Different types of design elements may be provided for depending on the system in question. By way of example, design element types such as the following may be provided: media elements which may be use to display various types of visual media (e.g. raster format images, vector graphic images, videos, and/or other visual media); text elements which may be used to display text; and/or elements of other types.

As will be appreciated, different attributes may be relevant to different element types. For example, any element that holds visual media will typically be associated with bounding box data that defines the element's position and size, while such data may not be relevant to an element that holds audio media. Accordingly, different element record data formats (with different attributes) may be used for different element types.

By way of example, an element record for a media type element may be as follows:

| Attribute | Note | E.g. |
|---|---|---|
| Type | A value defining the type of the element. | “type”: “MEDIA” |
| Position | Data defining the position of the element: e.g. an (x, y) | “position”: (100, 100) |
| | coordinate pair defining (for example) the top left point | |
| | of the element. | |
| Size | Data defining the size of the element: e.g. a (width, | “size”: (500, 400) |
| | height) pair. | |
| Rotation | Data defining any rotation of the element. | “rotation”: 0 |
| Opacity | Data defining any opacity of the element. | “opacity”: 1 |
| Media | Data that is or that provides a link/reference to media | “mediaID”: “M12345” |
| identifier | (e.g. a raster image, a vector graphic, a video) that the | |
| | element holds/is used to display | |

As described above, application 132 may provide a drag-and-drop interface for adding design elements to a design. To illustrate this, consider a user who wishes to add an image to a design they are creating. In this case, the user may search for an image via search control 312. In response, images matching the search criteria are identified and previews 314 of those images are displayed. A user may then drag a particular preview 314 and drop it onto the design 304 at a particular position. In response, an element record is generated (including, for example, position data based on where the image was dropped and an identifier of the image) and added to the design's elements array (e.g. by appending it to the end of the array).

The storage location for design data (e.g. design records) will depend on implementation. For example, in the networked environment described above design records are (ultimately) stored in/retrieved from the server environment's data storage 126. This involves the client application 132 communicating design data to the server environment 110—for example to the server application 114 which stores the data in data storage 126. Alternatively, or in addition, design data may be locally stored on a client system 130 (e.g. in non-transitory memory 210 thereof).

In the present disclosure, design elements are referred to as having bounding boxes. The bounding box of a given design element provides data on both the elements size and position in a design. An element's bounding box is a rectangular area which encloses that design element and may, for example, be considered as a set of four coordinates: (min x, max x, min y, max y). With the example element data above, a given element's bounding box may be calculated as: min x=position.x; max x=position.x+size.width; min y=position.y; max y=position.y+size.height.

In the example design format described above (and used herein), a design is a single page. In alternative implementations, however, a design may include multiple pages (with each page having one or more elements). In this case the design record format will be adapted to allow for different pages and their elements to be identified. The techniques described herein can be adapted for use with multi-page designs, e.g. by separately processing each page of a multi-page design to identify element groups.

In the present disclosure a distinction is drawn between a native format design and a raster format design. As used herein, a native format design is one that permits individual elements (with, for example, associated size and position data) to be independently selected and manipulated or edited by a user (human or programmatic). For example, with a native format design a user can select a specific element and edit its position, its size, its content (e.g. the media the element displays), and/or perform other editing operations. In contrast, a raster format design is a raster image that is composed of pixel values (e.g. RGB values). In a raster format design, pixel-level operations can be performed and individual elements may be visually observed by a user, but individual elements cannot be directly accessed and edited by a user.

As described further below, a native format design can be processed (rasterized) to generate a raster format version of that design. In this case both the native format design and the raster format design can be displayed (e.g. in a GUI such as 300 described above) and both the native format design and raster format design will look the same to a human observer (though there may some relatively minor visual differences may exist depending on the rasterization processing and parameters). The data underlying the two different format designs will, however, be very different. The raster format design will be described by a set of pixel values. In contrast, the native format design will be describe by data that describes design elements and their attributes (e.g. positions, sizes, media, etc.).

Turning to FIG. 4, a computer implemented method 400 for identifying design element groups in a native format design will be described. The operations of method 400 will be described as being performed by certain applications of the server environment 110. While the present embodiment describes specific operations as being performed by specific applications, the operations described could be performed by one or more other applications. For example, all operations of method 400 could be performed—or be adapted to be performed—by a single application (e.g. server application 114, client application 132, or an alternative application).

Method 400 may be triggered by various events.

As one example, method 400 may be manually triggered by user input. For example, a user may activate an identify design element groups control such as 322 described above. This cause client application 132 to generate and communicate an element grouping message to server application 114. The element grouping message may, for example, include data that identifies a particular native format design (e.g. the design currently displayed in display region 302 or another design identified by the user) and indicates that element grouping is to be performed. On receiving such an element grouping message, the server application 114 initiates processing in accordance with method 400.

As another example, method 400 may be automatically triggered when one or more events occur. For example, client application 132 may be configured to automatically generate and communicate an element grouping message and communicate it to the server application 114 when the client application 132 detects occurrence of a predefined event (which may be referred to as an update groups event). Predefined events may include, for example, one or more of: a new element being added to a native format design; an element being deleted from a native format design; a relevant edit operation being performed (discussed further below); a native format design being saved. In this context, relevant edit operations may include: resizing operations that change an element's size; repositioning operations that change an element's position; and/or other operations that may impact whether or not an element is part of an element group or not (e.g. edits that impact an element's rotation, transparency, or other relevant attributes). In still further embodiments, server application 114 itself may be configured to detect the occurrence of an update groups event and initiate processing in accordance with method 400 without receiving an element grouping message from a client application 132.

At 402, server application 114 accesses an input design (or data in respect thereof). The input design will be a native format design. The input design may, for example, be a design record as described above (though as noted alternative formats are possible). Generally speaking, however, the input design's data will define design elements and their attributes which will include attributes (e.g. size and position attributes) that allows element bounding boxes to be determined.

At 404, the input design retrieved at 402 is processed to generate a corresponding raster format design. This will be referred to as the design raster. In the present embodiment, the design raster is generated by rasterizer application 118 (referred to as application 118 for convenience). Rasterizer application 118 may use any appropriate code library, algorithm, or technique to process the input data accessed at 402 to generate the design raster from the design data.

In certain embodiments, application 118 is configured to generate a reduced size design raster at 404. In certain scenarios, generating a reduced size raster can reduce latency in a design group identification process as fewer image pixels need to be communicated and processed.

In order to generate a reduced size design raster, application 118 may be configured to generate the design raster so it has a reduced quality (relative to a maximum achievable rasterization quality) and a reduced resolution (when compared to the resolution of the input design). Alternatively, to generate a reduced size design raster the application 118 may be configured to generate the design raster so it has a reduced quality (and not a reduced resolution) or vice versa.

To generate a reduced quality design raster, application 118 may be configured to generate the design raster using a predefined quality setting that is less than the maximum quality achievable by the rasterization algorithm/approach that is used. By way of example, application 118 may generate a JPEG format raster using a quality value of 0.5 (on a scale of 0 to 1, or 50 on a scale of 0 to 100). Alternative sub-maximum quality values may be used.

To generate a reduced resolution design raster, application 118 may be configured so that design rasters are generated (or are downsized following initial generation) to have a maximum resolution. This may be achieved in various ways.

For example, application 118 may be configured so that the design raster's area (e.g. raster width*raster height) does not exceed does not exceed a defined maximum area. The defined maximum area may, for example, be 518400, though other values can be used. If the initial raster generated for the design exceeds the defined maximum area, application 118 uniformly scales the design raster (i.e. so that the aspect ratio of the input design maintained) so the maximum area is not exceeded.

As another example, in order to generate a reduced resolution design raster application 118 may be configured so that the largest (or equal largest) dimension of the design raster (which may be its width or height) does not exceed a defined maximum dimension value (e.g. a defined number of pixels). In this case, and assuming an input design that has a width and/or height that is greater than the defined maximum dimension value, application 118 will uniformly scale the design raster so that its largest (or equal largest) dimension is equal to the defined maximum dimension value. If neither the width nor the height of the input design exceeds the maximum dimension value, scaling need not be performed. By way of example, the defined maximum dimension value may be 960 pixels, though alternative values may be used.

By way of further example, application 118 may be configured to generate a reduced resolution raster by applying a predefined scaling factor. For example, application 118 may apply a scaling factor of 0.8 (or an alternative scaling factor), in which case a design raster with a resolution that is 80% of the size of the input design is generated. As another example, application 118 may be configured to apply different predefined scaling factors based on the resolution of the input design. In this case, relatively larger predefined scaling factors may be defined for and applied for input designs with relatively larger resolutions, and relatively smaller (or no) predefined scaling factors may be defined for and applied for input designs with relatively smaller resolutions.

In the present example, rasterization of the input design is a server-side operation. In alternative embodiments, however, rasterization may be performed by the client system 130 (e.g. by client application 132 or an alternative application) which then communicates the design raster to the server application 114 (or an alternative server-side application). In this case generating a reduced size design raster may be advantageous to reduce the time taken to communicate the design raster from the client system 130 to the sever environment 110 (and thus reduce the latency of the group identification process as a whole).

At 406, and in the present embodiment, the design raster generated at 404 is processed to identify objects in the design raster that correspond to design element groups and to classify each object that is identified as a particular type of design element group.

In the present embodiment, group identification and classification is performed by the object identification application 120 (referred to as application 120 for convenience). Object identification could, however, be performed by an alternative server- or client-side application.

In the present embodiments object identification and classification are performed together. These may, however, be considered as two distinct functions. In the present disclosure, object identification involves identifying objects in a design raster that correspond to design element groups. Each object that is identified is a region (i.e. an image region) of the design raster. For each object that is identified, classification involves classifying the type of the object, which in the present disclosure is a type of the element group that the object corresponds to.

Where classification is performed, different element group (that is, object) types are defined based on their semantic and visual meanings. Once an object has been classified, therefore, its classification provides semantic information in respect of the element group that the object corresponds to itself. This can enable better understanding of the semantic role of an element group in a design and, in some instances, better understanding of the design as a whole (e.g. based on the type(s) of element groups it includes). More specifically, an element group's type can be used by downstream applications to determine how that element group should be processed when performing a particular operation—e.g. when resizing a design (or element group within a design), converting a design from one format to another (which may involve reflowing the design's elements), and/or when performing other operations on an element group or a design that includes one or more element groups.

In the present embodiment, a hierarchy of group types is used. The hierarchy of group types includes main and sub types.

In the present embodiment, two main group types are defined. These will be referred to as the hard group type and the soft group type. An element group is classified as hard-type element group if the design elements within the group must remain in the same configuration if the group is processed in downstream operations. Conversely, an element group is classified as a soft-type element group if the design elements within the group can be reconfigured (e.g. re-ordered or repositioned) if the group is processed in downstream operations.

Beneath these two main group types, various group sub-types are defined. The precise sub-types defined may depend on the nature of the design platform in question and the types of element groups that commonly appear in designs that are generated using the system. Several examples of group sub-types are provided below with reference to the FIG. 5 which shows example native format design 304 (the design that is partially displayed in example GUI 300). Design 304 includes a number of design elements, and in FIG. 5, the bounding box of each design element is indicated by a broken line. Element bounding boxes are not typically displayed however may be in certain circumstances (e.g. if an element has been selected by a user).

One example hard group sub-type will be referred to as the composite graphic type element group. A composite graphic type group generally includes multiple graphics or images that overlap or are proximate each other. By way of example, in design 304 includes a composite type group that includes graphic (or image) elements 502 and 504. While elements 502 and 504 are depicted as a circle and a triangle for simplicity, element 502 could for example be a graphic or image of a person or animal and element 504 could be a graphic or image of a hat that has been positioned on top of the person or animal's head.

One example soft group sub-type will be referred to as a content block type element group. A content block type group generally includes media (e.g. an image or graphic) and text. Furthermore, a single design may have several content block type groups with the same types of elements in a similar arrangement. By way of example, design 304 includes: one content block type group that includes element 506 (an image element), element 508 (a text element with the text “text”), and element 510 (a graphic element that is a rounded corner rectangle); and another content block type group that includes element 512 (an image element), element 514 (a text element with the text “text”), and element 516 (a graphic element that is a rounded corner rectangle).

Another example hard group sub-type will be referred to as a graph type element group. A graph type group generally includes elements (e.g. graphic elements and text elements) that are arranged to provide information in a graph form that includes vertices (or nodes) and edges (e.g. lines) that join the vertices. By way of example, design 304 includes a graph type group that includes: elements 530, 532, and 534 (e.g. graphic elements with text of “Node 1”, “Node 2”, and “Node 3” respectively); and elements 536, 538, and 540 (e.g. graphic elements that are lines).

Another example hard group sub-type will be referred to as a chart type element group. A chart type group generally includes elements (e.g. graphic elements and text elements) that are arranged to provide a graphic representation of quantitative data along information concerning that data (e.g. captions or legends). By way of example, design 304 includes: one chart type group that includes element 518 (a graphic element), element 520 (a text element with the text “50%”), and element 522 (another text element with the text “more text”); and another chart type group that includes element 524 (a graphic element), element 526 (a text element with the text “90% t”), and element 528 (another text element with the text “more text”).

Another example hard group sub-type will be referred to as a diagram type element group. A diagram type group generally includes elements (e.g. text elements and graphic elements) that are arranged to provide information in a visual form. By way of example, design 304 includes a diagram type group that (in particular a Venn diagram) that includes: two graphic elements 542 and 544 (in this instance overlapping circles) and three text elements 546, 548, and 550 (in this instance with text “Region A”, “Region B”, and “Region C” respectively).

Another example hard group sub-type will be referred to as a table type element group. A table type group generally includes elements (e.g. text elements and graphic elements) that are arranged to provide information in a tabular format (e.g. rows and columns).

It will be appreciated that the group sub-types described above (and the specific elements and element types that are members of the example groups of those types) are provided by way of example. Additional and or alternative sub-groups may be provided.

In the present embodiment, application 120 is, or makes use of, a computer vision model that has been trained to process a design raster to identify and classify objects that correspond to element groups. This is described further below. In the present embodiment, the output of application 120 will be referred to as object data and includes a set of zero or more object records. Each object record corresponds to an object that application 120 has identified in the design raster (which, in turn, corresponds to an element group in the design) and includes region data and type data.

The region data of an object record includes values that indicate the region of the design raster that the identified object is located in. The region data may define a rectangular bounding box. This may be via a set of (min x, max x, min y, max y) values that indicate the corners of the bounding box, by a set of (x, y, width, height) values that indicate an (x and y) origin of the bounding box and its width and height, or by any other appropriate set of values.

The type data of an object record indicates the classification (i.e. the type) of the object and, therefore, the type of the element group that the object corresponds to. This may, for example, be a type identifier (e.g. a number or a string) that maps to a group sub-type (e.g. as described above).

For each identified object, application 120 may also output a confidence score—e.g. a value indicating how confident or otherwise application 120 is that the identified object is actually an element group of the type returned.

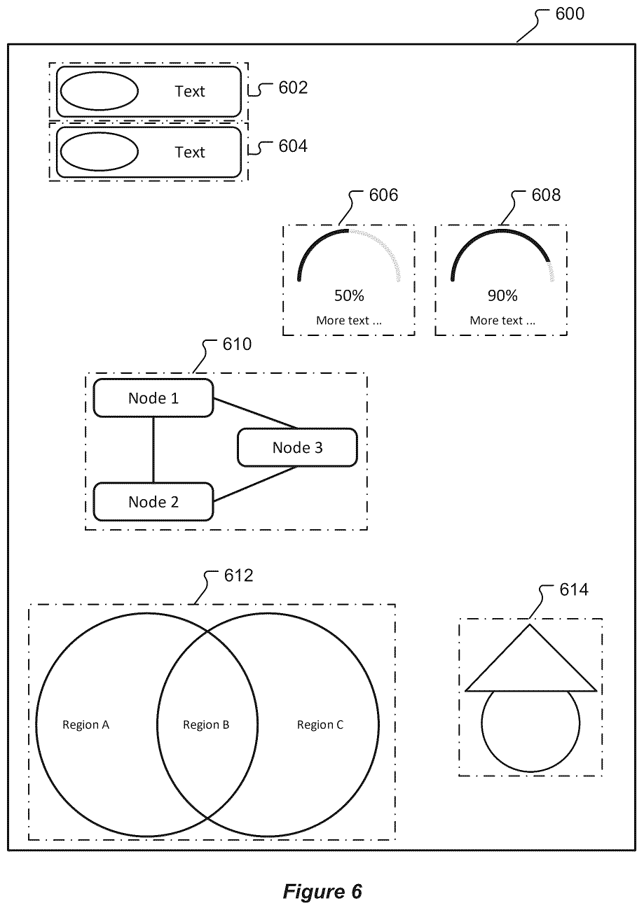

To illustrate this, consider FIG. 6 which depicts design raster 600 that corresponds to native format design 304 of FIG. 5. As discussed above, while raster 600 looks similar to design 304 it is a raster that is made up of pixels only. As such, raster format design does not have underlying information as to elements, element types, element sizes/positions etc. In this example, application 120 has identified seven objects: 602-614 in design raster 600. In FIG. 6 each object's region (e.g. as defined by region data) is indicated by a dot-dash line (which is not part of the design raster). In this example, the set of object records returned by application 120 may take a format such as the following:

```
“objectData”:{
  “object”:{“objectID”: “602”, “region”: [xₘᵢₙ, xₘₐₓ, yₘᵢₙ, yₘₐₓ], “type”: 1, “con”: n},
  “object”:{“objectID”: “604”, “region”: [xₘᵢₙ, xₘₐₓ, yₘᵢₙ, yₘₐₓ], “type”: 1, “con”: n },
  “object”:{“objectID”: “606”, “region”: [xₘᵢₙ, xₘₐₓ, yₘᵢₙ, yₘₐₓ], “type”: 2, “con”: n },
  “object”:{“objectID”: “608”, “region”: [xₘᵢₙ, xₘₐₓ, yₘᵢₙ, yₘₐₓ], “type”: 2, “con”: n },
  “object”:{“objectID”: “610”, “region”: [xₘᵢₙ, xₘₐₓ, yₘᵢₙ, yₘₐₓ], “type”: 3, “con”: n },
  “object”:{“objectID”: “612”, “region”: [xₘᵢₙ, xₘₐₓ, yₘᵢₙ, yₘₐₓ], “type”: 4, “con”: n },
  “object”:{“objectID”: “614”, “region”: [xₘᵢₙ, xₘₐₓ, yₘᵢₙ, yₘₐₓ], “type”: 5, “con”: n }
}
```

In this particular example, each object record is a JSON object that includes an object identifier, region data (an array indicating the bounding box of the image region that contains the object), object data (in this example a value that maps to the type of the identified group—e.g. “1” maps to the content block type group, “2” maps to the chart type group, “3” maps to the graph type group, “4” maps to the diagram type group, and “5” maps to the composite graphic type group), and a confidence score value.

Each object record corresponds to an element group in the input design. However, at 406 each object record refers to a region of a design raster (which is made up of pixels, not design elements).

At 408, design element groups corresponding to the objects identified at 406 (if any) are determined. Generally speaking, this involves processing each object that has been identified (e.g. processing each object record) to determine which elements of the input design belong to that object.

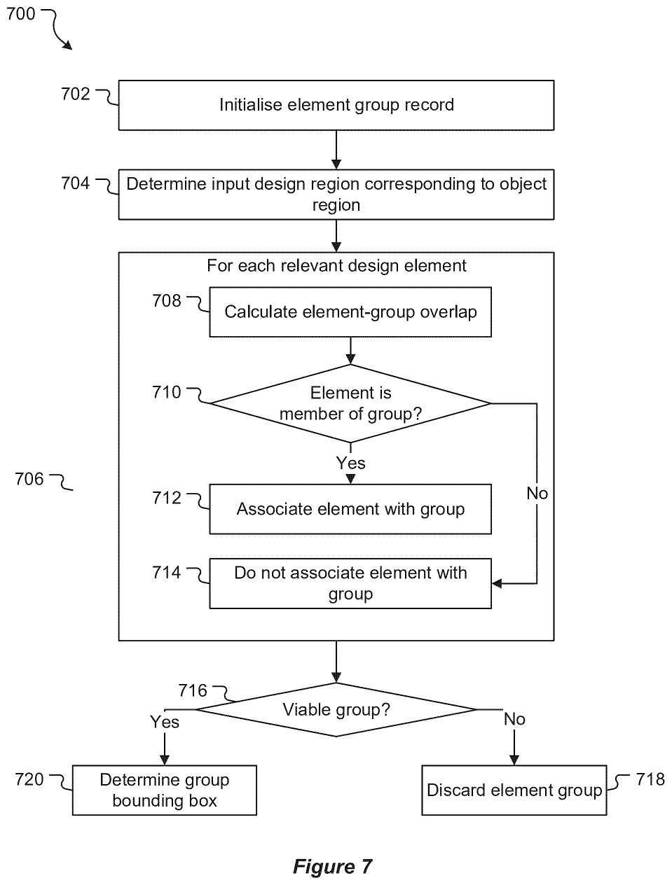

Turning to FIG. 7, a method 700 for determining an element group that corresponds to an identified object (and generating an element record in respect of that element group) will be described. In the present embodiment, the processing of method 700 is performed by the group determination application 122 (referred to as application 122 for convenience). Group determination could, however, be performed by an alternative server- or client-side application.

Application 122 may be configured to process all identified objects (e.g. object records) according to method 700 or a subset of the identified objects. For example, application 122 may be configured to only process objects with a confidence score that exceeds a minimum value. In the present implementation, application 122 is configured to order the objects that have been identified based on their confidence scores from highest confidence score to lowest confidence score and then process the objects sequentially in that order.

At 702, application 122 initialises an element group record for the object being processed (which will be referred to as the selected object). Element group records may take any appropriate format. In the present embodiment, each element group record includes a group identifier, group type data, group membership data (which identifies the elements that are members of the group, described below at 712), and group bounding box data (described below at 720). By way of specific example, each element group record may be a JSON object such as the following (thought alternative formats with additional/alternative attributes are possible):

```
“group”:{“groupID”: “602”,
  “groupType”: 1,
  “members”: [ ],
  “box”:[ ]},
```

In the present embodiment, application 122 initialises the element group record to include: the group ID of the selected object; the group type of the selected object; an empty membership array, and an empty bounding box array.

At 704, application 122 determines a region of the input design (referred to as the input design region) that corresponds to the selected object's region in the design raster (as determined by the object's region data). In order to determine the input design region, application 122 may need to translate the region data of the selected object. Translation will be required if the coordinate space of the design raster (which the object's region data is defined in) is not the same as the coordinate space of the input design (which the input design element sizes and positions are defined in). For example, if a reduced resolution design raster has been generated at 404 then application 122 will need to translate each object's region data to account for that reduced resolution.

If translation of the object's region is required, the precise calculations performed will depend on the operations performed when generating the design raster. E.g. if the design raster was scaled to 0.8 of the input design's size, then each object's region will need to be translated so it is effectively scaled back up to 1.0 of the original design's size.

At 706, application 122 determines input design elements that are members of the element group that the selected object corresponds to (the element group that the selected object corresponds to will be referred to as the selected element group). In the present embodiment, this involves processing each relevant design element to determine whether it is a member of the selected object or not.

In some instances, application 122 may determine that all input design elements are relevant design elements (and, therefore, all design elements are processed for the selected object at 706).

In other embodiments, application 122 may determine that one or more input design elements are not relevant (and therefore do not need to be processed for the selected object at 706). For example, in certain implementations application 122 may be configured to determine that input design elements of a particular type are not relevant. For example, application 122 may be configured to determine that audio type design elements (which may not be associated with any visual design features) are not relevant design elements. As another example, application 122 may be configured to determine that any input design element that has already been associated with an element group is not relevant (on the basis that an input design element will, at least in the present embodiments, only be able to be a member of one group).

Relevant design elements may processed at 706 sequentially (in any order or) in parallel. For example, application 122 may be configured to iterate through the input design's element array. For each element application 122 either determines that the element is a relevant element (and processes that element to determine whether it is a member of the selected group or not) or determines the element is not a relevant element (and foregoes processing that element to determine whether it is a member of the selected group or not).

In the present embodiment, in order to determine whether a selected (relevant) design element is a member of a selected element group operations 708, 710, 712 and 714 are performed.

At 708, application 122 calculates an element-group overlap in respect of the selected design element and the selected element group. This value is the size of the area (e.g. in pixels) that the selected design element and the selected element group overlap. The element-group overlap is calculated based on the design element's bounding box and the input design region determined at 704 (which is the region of the input design that corresponds to the object's region in the design raster). Application 122 may be configured to calculate the element-group overlap in various ways. For example, if the selected design element's bounding box is defined as [Exₘᵢₙ, Exₘₐₓ, Eyₘᵢₙ, Eyₘₐₓ] and the input design region for the selected element group is defined as [Gxₘᵢₙ, Gxₘₐₓ, Gyₘᵢₙ, Gyₘₐₓ], the element-group overlap may be calculated as the x-coordinate overlap of the element bounding box and input design region (if any) multiplied by the y-coordinate overlap of the element bounding box and input design region (if any). E.g.:

$$max ( 0 , min ( {Ex}_{max} , {Gx}_{max} ) - max ( {Ex}_{min} , {Gx}_{min} ) ) * max ( 0 , min ( {Ey}_{max} , {Gy}_{max} ) - max ( {Ey}_{min} , {Gy}_{min} ) )$$

At 710, application 122 determines whether selected element is a member of the selected element group or not. In the present embodiment, application 122 is configured to determine this based on the size and position of the selected element (e.g. its bounding box) and the size and position of the input design region determined for the selected group (e.g. the region of the input design that corresponds to the selected object's region in the design raster).

In certain embodiments, application 122 is configured to determine that the selected element is a member of the selected element group only if it falls entirely within the input design region.

In alternative embodiments, application 122 is configured to determine that the selected element is a member of the selected element group if it falls partially within the input design region (or, phrased alternatively, even if the selected element falls partially outside the input design region).

In one embodiment, application 122 determines whether the selected element is a member of the selected element group by calculating whether the ratio of the element-group overlap (as calculated at 708) to the area of the selected design element (which may be calculated as its width by its height) meets a defined overlap threshold value x. E.g. if

$$\frac{element - group overlap}{area of the selected design element} \geq x$$

application 122 will determine that the selected design element is a member of the selected element group. Otherwise, application 122 will determine that the selected design element is not a member of the selected element group.

In the present embodiment, and based on evaluation and analysis, an overlap threshold value of x=0.7 is used. Alternative overlap threshold values are, however, possible.

If, at 710, application 122 determines that the selected element does belong to the selected element group, processing proceeds to 712 where the selected element is associated with the selected element group. This association may be performed in various ways. With the example element record format described above, application 122 may associate a selected element with the selected element group by adding (e.g. appending) an identifier of the selected element (e.g. its position in the input design's element array) to the members array of the element group record initialised at 702.

If, at 710, application 122 determines that the selected element does not belong to the selected element group, the selected element is not associated with the selected element group (as indicated at 714).

Once the selected element has been associated or not associated with selected element group, processing the selected element is complete (at least for that selected object). In this case, if any relevant input design elements have not been processed for the selected object, application 122 selects a new input design element and processes it for the selected object. If all relevant input design elements have been processed for the selected object, processing proceeds to 716.

At 716, all relevant input design elements have been processed for the selected object. In the present embodiment, application 122 determines whether the present element group is a viable group. In the present embodiment this determination is based on a set of group membership rules that are designed to provide a sanity check on the objects that have been identified and the groups generated based on those objects. Application 122 may be configured to enforce various group membership rules for this purpose. As one example, a group membership rule may require an element group to have more than one element associated with it. As another example, a group membership rule may require that if the group type is composite graphic type group it must have at least one image type element (or all elements must be image type elements). As another example, a group membership rule may require that if the group type is chart type group it must have at least one text type element (or must have at least one text type element and at least one image type element).

If application 122 determines that the group is not a viable group (e.g. as one or more group membership rules have been contravened), processing proceeds to 718 where the group is discarded (e.g. the element group record is deleted).

If application 122 determines that the group is not a viable group (e.g. as one or more group membership rules have been contravened), processing proceeds to 720. In the present embodiment, application 122 determines a group bounding box for the element group at 720. Application 122 determines the group bounding box based on the bounding boxes of the elements that have been determined to be members of the element group (and, as such, have been associated with the element group at 714). For example, the element group bounding box values may be calculated as:

$$x = minimum x coordinate of all member elements$$

$$y = minimum y coordinate of all member elements$$

$$Width = maximum x coordinate of all member elements - x$$

$$Height = maximum y coordinate of all member elements - y$$

Element group bounding boxes may be defined using alternative values, for example a set of (min x, max x, min y, and max y) values.

The group bounding box determined at 714 will typically be a more precise bounding box than a bounding box based on the selected object's region data (which was determined by the computer vision model).

Once the element group bounding box has been determined application 122 adds it to the element group record initialised at 702. Determination of the element group corresponding to the selected object (and generation of the group record corresponding to that element group) is then complete.

To illustrate the operation of operation block 408 and method 700, the below table provides example element group data (i.e. a set of element group records) that correspond to the example set of object records provided above:

```
“elementGroupData”: {
  “group”:{“groupID”: “602”,
    “groupType”: 1,
    “members”: [506, 508, 510],
    “box”:[x,y,w,h]},
  “group”:{“groupID”: “604”,
    “groupType”: 1,
    “members”: [512, 514, 516],
    “box”:[x,y,w,h]},
  “group”:{“groupID”: “606”,
    “groupType”: 2,
    “members”: [518, 520, 522],
    “box”:[x,y,w,h]},
  “group”:{“groupID”: “608”,
    “groupType”: 2,
    “members”: [524, 526, 528],
    “box”:[x,y,w,h]},
  “group”:{“groupID”: “610”,
    “groupType”: 3,
    “members”: [530, 532, 534, 536, 538, 540],
    “box”:[x,y,w,h]},
  “group”:{“groupID”: “612”,
    “groupType”: 4,
    “members”: [542, 544, 546, 548, 550],
    “box”:[x,y,w,h]},
  “group”:{“groupID”: “614”,
    “groupType”: 5,
    “members”: [502, 504],
    “box”:[x,y,w,h]}
```

At 410, the element groups that have been identified are output. This may involve various operations.

In the present implementation, outputting the element groups includes associating element group data (e.g. a set of element group records) with the input design. To do this, server application 114 (or an alternative application) may update the design record for the input design to include the element group data—e.g. the set of element group records generated at 408. The element group data allows each distinct element group to be identified and, for each element group, identifies the element members of the group, the bounding box for the group, and the type of the group. By associating element group data with the input design it can be provided to (or accessed by) downstream applications that may wish to make use of the element groups when processing the input design.

In some instances the design data for an input design may already include data in respect of existing element groups. This will be the case, for example, if a user has explicitly/manually defined element groups in the design and/or the design was based on a template design that included one or existing more element groups. In this case, the automatically identified element groups are stored in addition to any pre-existing element groups and are identified as automatically identified element groups (as distinct to pre-existing element groups).

In some instances, for example if method 400 was triggered by a user interaction, outputting element groups may further involve causing client application 132 to display the element groups in a user interface—e.g. in an editor user interface such as GUI 300 described above. In order to display element groups, client application 132 may, for example, generate and display bounding boxes (or bounding box regions) in the editor UI based on each element group's bounding box data. Bounding boxes may be displayed in various ways, for example by use of bounding box outlines, partially transparent overlays, flashing overlays/bounding box lines, and/or by any other appropriate mechanism.

In some instances, method 400 may be triggered by another application as part of the processing that other application is performing on the input design. In this case outputting the element groups will involve communicating the element group data to the application that triggered method 400.

In the example above, method 400 operates to both identify and classify element groups. In alternative embodiments, method 400 may be adapted to identify element groups (and the member elements of those groups, e.g. per 408) without classifying the groups. In this case a different (or differently trained) computer vision model may be used at 406—or the same model may be used but the classification information generated by the model disregarded.

As described above, in the present embodiments application 120 is, or makes use of, a computer vision model that has been trained to identify and classify objects that correspond to element groups in images. Various computer vision models may be used to identify and classify element groups in images (or to solely identify element groups in images if classification is not to be performed).

The following describes embodiments of the present disclosure which are concerned with generating a computer vision model that is trained to identify and classify element groups in an image (and can be used to perform the processing of application 120 as described above) and with generating training data that can be used to train such a model.

The operations performed to generate a trained computer vision model are performed by an application running on more computer processing systems. Generating the trained computer vision model may be performed by any appropriate computer processing system or set of computer processing systems-including, for example, a system such as client system 130 operating alone or in conjunction with one or more server-side applications.

In the present embodiments, the computer vision model that is used to identify and classify element groups in an image is a trained vision transformer-based object detection model. In particular, the trained machine learning model may be based on a You Only Look at One Sequence (YOLOS) model as described in the paper “You Only Look at One Sequence: Rethinking Transformer in Vision through Object Detection” by Yuxin Fang, Bencheng Liao, Xinggang Wang, Jiemin Fang, Jiyang Qi, Rui Wu, Jianwei Niu, Wenyu Liu (arXiv:2106.00666). Alternative machine learning models (and alternative machine learning model architectures) may, however, be used.

In order to generate the trained computer vision model based on the YOLOS model, various parameters may be initialised in various ways that will be apparent to the skilled addressee. By way of example, however, these may include parameters such as decay rate, learning rate, epochs, batch size, and/or any other parameter relevant to the computer vision model. As will be apparent to the skilled addressee, model parameters may be manually determined (e.g. through experimentation) and/or automatically determined (e.g. via a hyperparameter tuning process). As will also be apparent to the skilled addressee, the model parameters will depend on various factors such as the training data that is available and used to train the model, the computational resources available to train the model, the desired learning speed, and a variety of other factors. By way of illustration, however, example parameters may include: epochs=250; batch size=4; learning rate=1e-4; weight decay=1e-4.

Once required parameters of the computer vision model defined, the model is trained using a training dataset. The training dataset includes a number of training examples. In the present embodiment, each training example is associated with a design raster and a set of 0 or more object records. In the present embodiments, each object record takes the same form as the object records described above and includes region data (that indicates a region of the design raster that corresponds to an element group in a design that the design raster corresponds to) and type data (that indicates a type of the element group the region encloses).

In addition, a training example may be associated with a design identifier that allows the underlying design of the training example to be retrieved (e.g. a design record in respect of the design that the training example's design raster is based on) and element group data in respect of that design (e.g. a set of element group records the same or similar to those described above). While the design identifier (and underlying design) and element group data may not be directly used in training the computer vision model, this data may be used to evaluate the performance of the overall group identification process (including mapping operations 408).

In some instances, design rasters are not stored for training examples but are instead generated at the time of training (e.g. by rasterizing the underlying design as per 404)

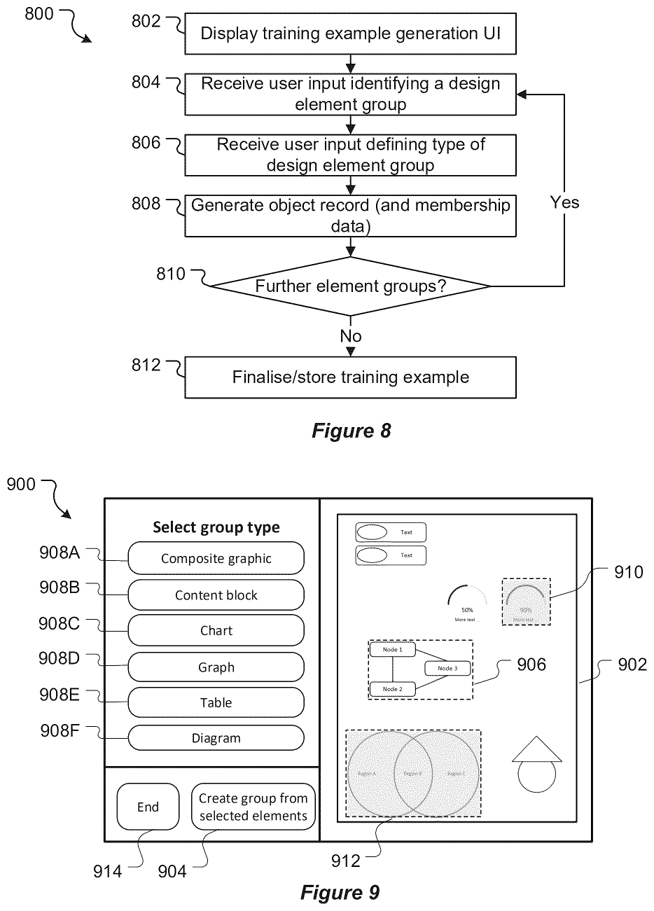

Example methods for generating training examples are below with reference to FIGS. 8, 10, and 13.

Generally speaking, and as will be known to skilled addressees, training the computer vision model involves initialising parameters of the model (e.g. weights and biases, which may be initialised to 0 or other random values) and processing the design raster each training example to identify and classify objects (which in this example correspond to element groups) in the design raster. The output for each training example (which may be a set of element group datasets as described above) is then compared to the training example's element group record in order to calculate a training example loss (and, ultimately, a total loss for the model in its current state).

Training of the computer vision model may continue until a desired number of epochs is reached, or a defined early stopping condition occurs. As one example, an early stopping condition may be that the loss for the validation set starts to increase rather than decrease. Additional or alternative early stopping conditions may be defined.

If the desired number of epochs has not been reached and no early stopping condition exists, the model is trained using back propagation to calculate new model parameters (e.g. weights and biases).

As noted above, in order to train the computer vision model that is used at 406 to identify and classify element groups in a design raster, a set of training examples is required. In order to generate a set of training examples, the present disclosure describes methods for generating what will be referred to as original training examples (that are generated based on user input) and synthetic training examples (that are automatically generated based on existing training examples).

Turning to FIG. 8, a method 800 for generating an original training example will be described. Method 800 is described as being performed by a client application such as 132, however the operations could be performed by one or more alternative applications.

At 802, application 132 display a training example generation UI. Client application 132 may interact with a server side application (such as training data generation application 124) to do so. The training example generation UI displays a design and includes one or more control mechanisms that allow a user to manually identify element groups and define the types of those element groups.

The design displayed in the training example generation UI may be a native format design or a design raster. Advantageously (though not essentially), however, a native format design will be displayed as this will permit more precise user identification of element groups.

FIG. 9 provides one example of a training example generation GUI 900 that may be displayed by a client application such as application 132. GUI 900 includes a design display region 902 that displays a design or part thereof. The design may correspond to any existing design that is available to the design platform (e.g. a design stored in data storage 126 or elsewhere). In certain embodiments, the design displayed is a design template that is available to the design platform.

At 804, application 132 receives user input that identifies a design element group. Various user inputs are possible depending on the mechanism(s) provided by the user interface.

By way of example, application 132 may enable a user to identify a design element group by selecting a region of the design 902 that is displayed (e.g. by drawing a rectangle or other shape using a cursor control device 224 and/or interaction with a touch screen display 214). An example of this is region 906 in FIG. 9, which depicts a user-selected region. Identifying design element groups by selecting a region is possible whether the design displayed (e.g. design 902) is a native format design or a raster format design.

In addition, or alternatively, application 132 may enable a user to identify a design element group by select specific design elements (e.g. by clicking on or contacting those elements) of the displayed design. Once all elements of an element group have been selected, a user may indicate this by activation of a control (such as a type selection control 908 described below, or a control such as control 904 of GUI 900. Identifying a design element group by selecting specific design elements is possible if the design displayed is a native format design but is not possible (at least not without further object recognition type processing) if the design displayed is a raster format design.

At 806, application 132 receives user input that defines a type of the design element group identified at 804. Various user inputs for defining a type of element group are possible.

By way of example, application 132 may display a set of type controls (e.g. 908A-908F) and a user can define the type of the element group by activating the appropriate type control 908. As a further example, application 132 may also (or alternatively) allow a user to specify an element group type by performing a secondary user interaction (e.g. a right click or a dwell) once an element group has been on a selected and, in response, displaying one or more group type selection controls that allow the user to specify the element group type.

At 808 application 132 generates an object record in respect of the element group that has been identified. In certain embodiments, if the design displayed is a native format design application 132 also generates a group membership data that records identifiers of the elements that are members of the identified group.

In order to generate the object record, application 132 determines region data and type data. (If a group identifier is used this may be automatically generated.)

Application 132 may be configured to determine the region data in various ways. For example, if the element group is identified by a user drawing rectangular region on the design, application 132 may base the object record's region data on the bounds of the drawn rectangle. Alternatively, if the design is a native format design and the element members of the group are known, application 132 may be configured determine the object record's region data based on the bounding boxes of the elements that are within the region drawn by the user (or, in some instances, based on the actual content of those elements). This may provide a more precise region than the drawn region.

If the element group is identified by a user selecting specific elements, application 132 will determine the object record's region based on the bounding boxes of the selected elements (or, in some instances, based on the actual content of those elements).

Application 132 generates the object record's type data based on the group type defined by the user at 806.

If group membership data is also generated, application 132 is configured to determine the elements that are members of the element group. If the element group is identified by user inputs directly selecting elements the membership data is generated based on the selected elements. Alternatively, if the element group is identified by user input drawing or otherwise selecting a region, application 132 determines the elements that fall within the region (based on the design element bounding boxes) and records those elements as members of the group. Where generated, group membership data for a particular element group may be included in or otherwise associated with the object record for that element group.

In the present embodiment, once an element group has been identified, application 132 visually indicates the element group (or the elements thereof) in the user interface. This allows a user to see what element groups that have already been identified in the design that is displayed. Examples of this are shaded regions 910 and 912 of GUI 900, which indicate that a user has already identified element groups that include the elements in the shaded regions. Where multiple design element groups have been identified, application 132 may visually distinguish those groups from one another—e.g. a first design element group (or the elements thereof) may be visually indicated by a first colour and a second design element group (or the elements thereof) may be visually indicated by a second colour. Alternative techniques for visually indicating and/or distinguishing between element groups that have already been defined may be used.

At 810, application determines whether the user wishes to identify further element groups in the displayed design or to finalise the training example. If further element groups are to be identified, processing returns to 804. This may be determined, for example, if user input identifying a new element group in the design is received (or, alternatively, if an explicit “identify new element group” control (not shown) is activated).

If the training example is complete, processing proceeds to 812. This may be determined, for example, by activation of an “end” control such as 914.

At 812, application 132 finalises and stores the training example. In order to finalise the training example, application 132 associates the object records (and, if generated, element group records or group membership data) generated at 808 with the design (e.g. an identifier of the design). In some instances, and if the design was a native format design, finalising the training example may involve rasterising the design (e.g. per 404 above) and adding the raster data (or a link/reference to a location that the design raster saved) to the training example.

In the present embodiment, the training example is stored at server environment 110. Accordingly, application 132 communicates the training example data to training data generation application 124 (or an alternative server-side application) which then stores the training example (e.g. on data storage 126).

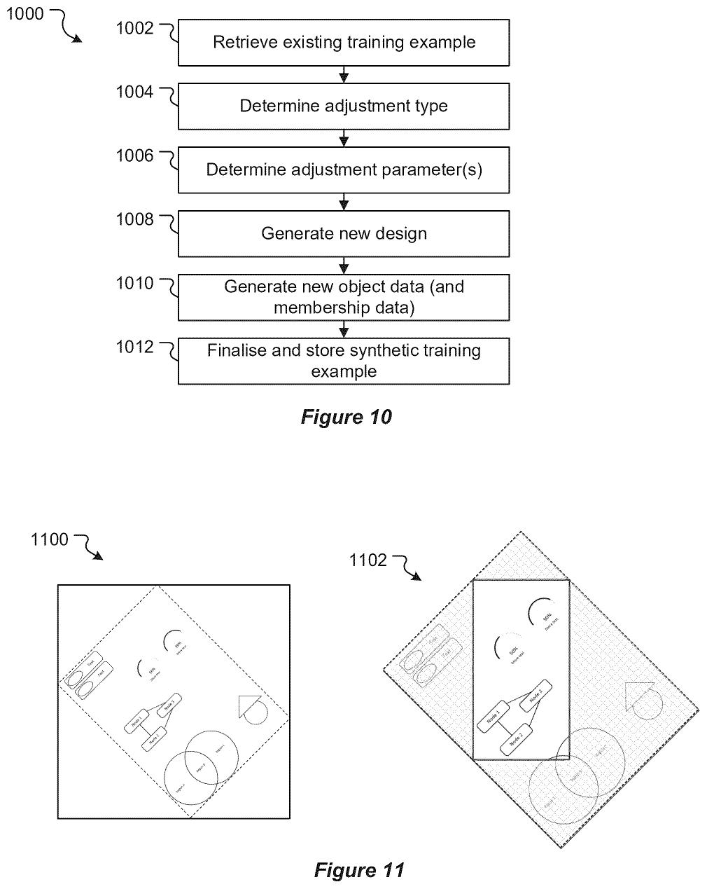

Turning to FIG. 10, a method 1000 for generating one or more synthetic training examples based on an existing training example will be described. Method 1000 is described as being performed by a training data generation application 124 (referred to as application 124 for convenience), however could be performed by one (or more) other client or server side applications.

Generally speaking, method 1000 involves retrieving an existing training example, determining an adjustment, and generating a new (synthetic) training example based on the existing training example and the adjustment. This in turn involves adjusting the design that the existing training example is associated with based on the adjustment that is determined (thus generating a new design for the new training example) and generating new object data based on the element groups in the new design. Each element group in the new design will correspond to an element group in the existing design (i.e. the design of the existing training example), however the positions/sizes of the element groups will (at least for some adjustments) have changed due to the adjustment performed. Further, in some cases an adjustment may result in one or more element groups from the existing design not existing (or only partially existing) in the new design.

At 1002, application 124 retrieves an existing training example (e.g. from data storage 126 or an alternative location). As described above, the existing training example will be associated with a design (which will be referred to as the existing design) and object data (e.g. a set of object records, which will be referred to as the existing object data). The existing design of at training example may be a native format design or a raster format design. If the existing design is a native format design, the existing training example may also be associated with group membership data that identifies the design elements that are members of each object/element group (which will be referred to as the existing group membership data).

The existing training example may be an original training example (generated, for example, according to method 800 described above) or may itself be a synthetic training example that has already been generated (e.g. according to method 1000 or method 1300).

At 1004, application 124 selects a type adjustment that is to be performed to the existing design in order to generate the new training example. In the present embodiment, the types of adjustment that can be determined include a rotation adjustment, a crop adjustment, a flip adjustment, a colour adjustment, and a scale adjustment. Application 124 may be configured to select from (and perform) additional or fewer adjustments.

Application 124 may be configured determine the adjustment for the training example retrieved at 1002 in various ways. For example, application 124 may be configured to randomly select an adjustment type from those available. Alternatively, application 124 may cycle through the available adjustment types for successive existing training examples. Still further, application 124 may be configured process the existing training retrieved at 1002 example according to each available adjustment (i.e. to repeat operations 1002-1012 for the existing training example for each adjustment, resulting in multiple synthetic training examples being generated based on the same existing training example).

At 1006, application 124 determines parameters for the adjustment determined at 1006. The parameters determined will depend on the type of adjustment.

For a rotation adjustment, application 124 determines a rotation value. Application 124 may be configured to randomly determine a rotation value between 0 and 360 degrees (though the rotation value may be alternatively determined and/or be a value within a different range).

For a crop adjustment, application 124 determines a crop that is to be applied to the design of the existing training example. Application 124 may be configured to determine the crop randomly or in an alternative way.

For a flip adjustment, application 124 determines the flip that is to be applied to the design of the existing training example. Application 124 may randomly (or otherwise) determine to flip on the horizontal axis, the vertical axis, or both the horizontal and vertical axes.

For a colour adjustment, application 124 determines a particular colour adjustment from a set of available colour adjustments. By way of example, the available colour adjustments may include one or more of: a colour normalisation adjustment (which involves normalising the RGB values of the pixels of the design); a greyscale adjustment (which involves converting the design to greyscale); and/or an alternative colour adjustment.

For a scale adjustment, application 124 determines a scale value. Application 124 may be configured to randomly (or otherwise) determine a scale value from within a defined scaling range. By way of example, the defined scaling range may be 2 to 3 (though alternative ranges may be used).

At 1008 application 124 generates a new design based on the existing design, the adjustment type determined at 1004, and the adjustment parameter(s) determined at 1006. This is described further below. If the existing design is a native format design, application 124 may be configured to generate the new design as either a native format design or a raster format design. In one embodiment, if the existing design is a native format design application 124 is configured to generate the new design as a native format design as it may be higher quality than a raster (and can always be used to generate a raster if need be). If the existing design is a raster format design, application 124 will generate the new design as a raster format design.

For a rotation adjustment, application 124 generates the new design at 1008 by rotating the existing design by the rotation value determined at 1006.

In certain implementations, application 124 is configured to generate the new design to have a new width and a new height that accommodate the entirety of the rotated design (an operation that leaves corners of the new design empty). An example of this is design 1100 of FIG. 11, which is a version of design 304 rotated by 45 degrees (the original edges of design 304 shown in broken line for illustrative purposes). As can be seen, the width and height of design 1100 have been expanded to encompass the entirety of the rotated design and as a result the four corners of the design are empty.

In an alternative embodiment, application 124 is configured to generate the new design by cropping the rotated design to a maximum width and height that does not leave any empty space. Cropping a design in this manner may cause one or more objects (or element groups) that are present in the existing design (e.g. in the existing object data) to be partially or entirely cropped out of the new design. An example of this is design 1102 of FIG. 11, which is also a version of design 304 rotated by 45 degrees. In this example, the rotated design has been cropped so there is no empty space. As a result, however, the corners of design 1102 that are shown with hatching (and the elements in those portions) are no longer part of design 1102.

For a crop adjustment, application 124 generates the new design at 1008 by cropping the existing design based on the crop parameter determined at 1006.

For a flip adjustment, application 124 generates the new design at 1008 by flipping the existing design based on the flip parameter determined at 1006.

For a colour adjustment, application 124 generates the new design at 1008 by processes the existing design according to the particular colour adjustment determined at 1006. In certain embodiments, applying a colour adjustment to the existing design may be better (or more efficiently) performed by working on a raster format design. In this case, and if the existing design is a native format design, application 124 may generate a corresponding raster format design.

For a scale adjustment, application 124 generates the new design at 1008 by scaling the existing design based on the scale value determined at 1006.

At 1010, following generation of the new design, application 124 generates object (and, optionally, membership) data for the new training example.

In the present embodiment, application 124 generates the new object data based on the existing object data (e.g. by copying the existing object data).

As described above, for certain types of adjustments (e.g. rotating and cropping) element groups that were present in the existing design may not be present (or may be only partially present) in the new design due to cropping. In this case, application 124 determines whether any element groups of the existing training example no longer exist (or only partially exist) in the new design. If application 124 determines that an element group of the existing training example does not exist (or only partially exists) in the new design, application 124 removes the object record in respect of that element group from the new object data.

As also described above, certain types of adjustments (e.g. rotating, flipping, scaling) will result in the sizes and/or positions of the original element groups changing. In this case, application 124 also calculates new region data (e.g. bounding boxes) for each element group in the new design and records this in the object data.

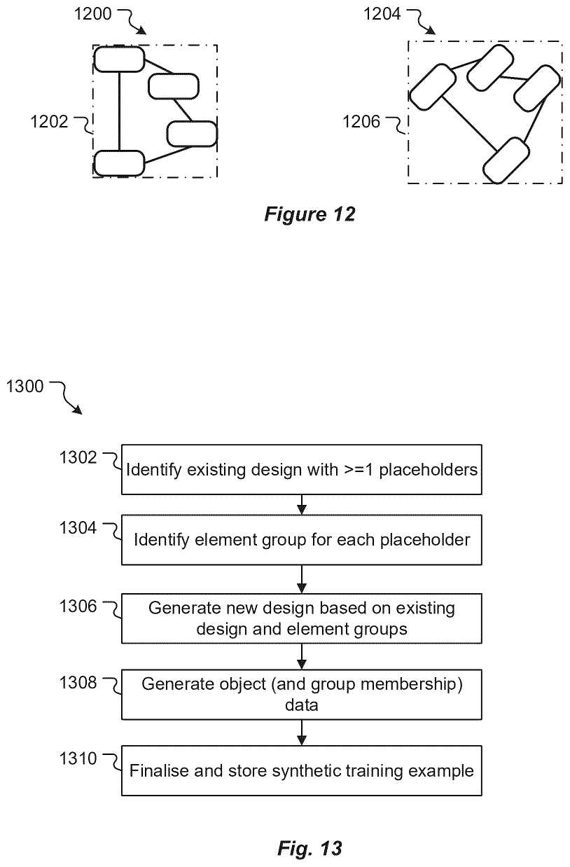

For example, in the present embodiments region data defines a non-rotated bounding box (that is a bounding box with edges that are vertical and horizontal). Accordingly, when a new design is generated based on a rotation new bounding boxes (or object regions) will need to be calculated to take the rotation that has been applied into account. To illustrate this, consider FIG. 12 which depicts: an original (un-rotated) element group 1200 with its original bounding box 1202; and a version 1204 of that element group that has been rotated by 45 degrees as well as the rotated group's recalculated bounding box 1206.

In some embodiments, and if the existing design is a native format design, application 124 may also generate group membership data at 1010. In this case, the group membership data may be based on the group membership data of the existing training example or may be generated anew based on the new (native format) design generated at 1008. In either case, if any element group from the original design no longer exists (or only partially exists) in the new design, application 124 will not include (or generate anew) membership data for that group.

At 1012, application 124 finalises and stores the new synthetic training example. This may be similar to 812 above.

By applying the techniques described above, application 124 may be configured to generate multiple synthetic training examples from a single existing training example—i.e. by determining different adjustment types and/or by determining different adjustment parameters for the same adjustment type.

Furthermore, a synthetic training example may be generated from an existing training example by combining two or more of the adjustments described above. For example, an existing training example may be flipped and rotated.

Method 1000 will typically be performed on multiple existing training examples. By generating synthetic training examples in this way, a large set of training examples can be generated based on relatively few original (or existing) training examples. Moreover, generating synthetic training examples in this way helps to ensure that the set of training examples (as a whole) is varied. This, in turn, allows the computer vision model to learn and perform better.

Turning to FIG. 13, a method 1300 for generating what will be referred to as a group transferred synthetic training example will be described. Method 1130 is described as being performed by a training data generation application 124 (referred to as application 124 for convenience), however could be performed by one (or more) other client or server side applications.

Generally speaking, method 1300 operates to transfer an existing and known element group from one native format design (e.g. the native format design that element group is originally part of) to another existing native format design and then to generate a training example based on the resulting design.

In the present embodiments, method 1300 relies on the design platform having native format template designs available that include designated place-holder elements. For example, design platform may have a library of native format template design that are available to users to use in creating their own designs. Such template designs will include various design elements that are appropriate to the type of template. Furthermore, one or more elements of a given template design may be designated as a placeholder element: that is, an element that is intended to be replaced by a new element (or to have its media replaced by new media) when the template is used to create a new design. A placeholder element in a template design may be identified in any appropriate way, e.g. by an element-level attribute that is set to indicate the element is a placeholder, or a design level attribute that stores (for example) identifiers of any placeholder elements included in the template design. Template designs may be stored, for example, in data storage 126.

At 1302, application 124 identifies an existing native format design that includes one or more placeholder elements. As discussed, this may be a template design with one or more elements that are designated as placeholders.

At 1304, application 124 identifies an existing element group for at least one (though typically each) placeholder that is in the existing design identified at 1302.

In the present embodiment, application 124 identifies existing element groups from existing training examples. In particular, application 124 may identify existing element groups based on group membership data associated with existing training examples. As described above, in a given training example object records (that define element groups) may include or be associated with group membership data that provides identifiers of the design elements that are members of that group.

In certain implementations, application 124 may be configured to determine that any existing element group can be used in any placeholder.

In alternative implementations, application 124 is configured to perform a compatibility check so that an existing element group can only be selected for a particular placeholder element if certain compatibility criteria are met.

By way of example, application 124 may be configured to enforce an aspect ratio compatibility criteria. In particular, application 124 may be configured to determine that an element group is only compatible with a placeholder element if the aspect ratio of the element group (which may, for example, be determined from the region data of the group's object record) and the aspect ratio of the placeholder element (which may be determined from the element's data—e.g. its height and width attributes) are compatible. Application 124 may determine that the aspect ratios are compatible in various ways. For example, application 124 may determine that aspect ratios are compatible if:

absolute value (element group aspect ratio-placeholder element aspect ratio)<=x x, which may be referred to as an aspect ratio threshold, may be set to 0 (in which case the aspect ratios will need to be the same to be compatible). Alternatively, x may be set to a value that permits some difference in the aspect ratios (e.g. 0.2, 0.1, or some other value).

Application 124 may also, or alternatively, be configured to enforce a size compatibility criteria. In particular, application 124 may be configured to determine that an element group is only compatible with a placeholder element if the size of the element group (which may be determined from its element group record) and the size of the placeholder element (which may be determined from the element's data—e.g. its height and width attributes) are compatible.

Application 124 may determine that the sizes are compatible in various ways. For example, application 124 may determine that sizes are compatible if:

y<=element group area/placeholder element area<=z

y and z, which may be referred to as the size range, may both be set to 1 (in which case the sizes will need to be the same to be compatible). Alternatively, y and z may be set to values that permit some difference in the sizes (e.g. y=0.8 and x=1.25, or alternative values).

If no compatible element group can be identified for any of an existing design's placeholder elements processing may return to 1302 to identify an alternative existing design.

If a compatible element group can be identified for some but not all of an existing design's placeholder elements, application 124 may be configured to proceed (without an element group for one or more placeholder elements) or to return to 1302 to identify an alternative existing design.

At 1306, application 124 generates a new native format design based on the existing design (identified at 1302) and the element group(s) (identified at 1304). For example, application 124 may create a copy of the existing design. For each placeholder element, application 124 may then replace (or update) the placeholder element with an element group that is based on the element group that has been identified for that placeholder.

When replacing (or updating) a selected placeholder element based on a selected element group, application 124 may create a new element group, The new element group will include the same elements as the selected element group, however application 124 will need to calculate new element positions (and/or sizes) to account for the group's new position (which is determined based on the placeholder element's position). In this case, however, the relative size and positions between elements in the element group is maintained.

As an alternative example, application 124 may generate a raster version of the existing element group and use that raster version of the existing element group as a fill (e.g. an image fill) for the placeholder element.

In some instances, the size of the element group may not be the same as the size of the placeholder element. In this case application 124 is configured to uniformly scale the existing element group (or the element members thereof) to fit the size of the placeholder element.

Similarly, in some instances, the aspect ratio of the element group may not be the same as the aspect ratio of the placeholder element. In this case, application 124 may configured to keep the aspect ratio of the element group (accepting that the element group will not occupy the same space as the placeholder element). Alternatively, if the aspect ratio of the element group is not be the same as the aspect ratio of the placeholder element, and the element group is a soft type element groups, application 124 may adjust the element group so that it is the same aspect ratio as the placeholder element. This may result in (or require) reflowing of the element group's elements, but as the group is a soft-type group this is permissible.

At 1308, application 124 generates object (and optionally group membership) data for the new training example. This involves generating an object record for each element group that has been transferred to the new design. In generating the object record for a given element group the type of the element group remains the same. In order to determine the object's region data, however, application 124 will need to recalculate the position of the element group based on its position in the new design (which, in turn, is based on the position of the placeholder element that the element group is replacing/being added to).

If group membership data is also generated for inclusion in (or association with) the new training example, application 124 will generate this based on identifiers the elements in the new design (noting that if element identifiers are based on their positions in the new design's element array, the element identifiers in the new design may differ from the identifiers those elements had in the existing element group).

At 1310, application 124 finalises and stores the new synthetic training example. This may be similar to 812 above, noting that in this instance the new design that is generated at 1306 is a native format design, and as such if the training example is to include a raster format design (or link/reference thereto) the design generated at 1306 will need to be rasterized.

As will be appreciated, method 1300 provides a further mechanism for quickly and automatically building a set of training examples that can be used to train a computer vision model to identify and classify element groups in a design raster.

In the embodiments described above, the computer vision model is trained to both identify and classify element groups (and training data to train the model to do so is generated). In alternative embodiments, the computer vision model may be trained to identify element groups only (without classification). In this case a different type of computer vision model may be used, or the same type of computer vision model may be used but it may be trained differently. For example, a machine learning model may be generated and trained to identify a single type of object (an element group), and that single type of object may include many different types of element groups (e.g. as described above).

The following first set of numbered clauses describe additional, specific embodiments of the disclosure:
Clause 1. A computer implemented method including:
accessing input design data in respect of an input design that includes a plurality of design elements;
processing, by a computer processing unit, the input design data to generate a raster design that corresponds to the input design;
processing the raster design to identify a first object in the raster design, wherein the first object corresponds to a first element group;
determining members of the first element group, wherein determining the members of the first element group includes:
determining that a first design element of the plurality of design elements is a member of the first element group based on a position of the first design element in the input design and a position of the first object in the raster design; and
determining that a second design element of the plurality of design elements is a member of the first element group based on a position of the second design element in the input design and a position of the first object in the raster design; and
   generating a first element group record that includes an identifier of the first design element and an identifier of the second design element.
Clause 2. The computer implemented method of clause 1, wherein the method further includes determining a type of the first element group and including the type of the first element group in the first element group record.
Clause 3. The computer implemented method of clause 1 or clause 2, wherein:
the first object is associated with a first raster design region, the raster first raster region being a region of the first object in the design raster; and
determining that the first design element is a member of the first element group includes:
   determining a first input design region, the first input design region being a region of the input design that corresponds to the first raster design region; and
   determining that the first design element is a member of the first element group based on the position of the first design element and the first design region.
Clause 4. The computer implemented method of clause 3, wherein determining that the first design element is a member of the first element group includes determining that the first design element is located entirely within the first input design region.
Clause 5. The computer implemented method of clause 3, wherein determining that the first design element is a member of the first element group includes determining that the first design element is located partially within the first input design region.
Clause 6. The computer implemented method of any one of clauses 1 to 5, wherein processing the raster design to identify the first object in the raster design includes processing the raster design using a computer vision model that has been trained to identify objects corresponding to design element groups.
Clause 7. The computer implemented method of clause 3, wherein the computer vision model is a vision transformer model.
Clause 8. The computer implemented method of any one of clauses 1 to 7, wherein the raster design is a reduced size raster design and processing the input design data to generate the raster design includes one or both of: generating the raster design using a rasterization quality that is less than a maximum achievable rasterization quality; generating the raster design to have a resolution that is less than a resolution of the input design.
Clause 9. The computer implemented method of any one of clauses 1 to 8, wherein the method further includes determining bounding box data defining a bounding box of the first element group and including the bounding box data in the first element group record.
Clause 10. The computer implemented method of clause 9, wherein the bounding box data is based on a bounding box of the first design element and a bounding box of the second design element.
Clause 11. The computer implemented method of any one of clauses 1 to 10, further including:
causing the input design to be displayed in a graphical user interface (GUI); and
causing a visual indication that identifies the first element group to be displayed in the GUI.
Clause 12. The computer implemented method of clause 6 or clause 7, wherein the computer vision model is training using a training example generated by: a method according to any one of clauses 1 to 11 of the second clause set; a method according to any one of clauses 1 to 16 of the third clause set; and/or a method according to any one of clauses 1 to 6 of the fourth clause set.

The following second set of numbered clauses describe additional, specific embodiments of the disclosure:
Clause 1. A computer implemented method including:
displaying, on a display, a graphical user interface (GUI);
displaying, in the GUI, a design;
receiving a first user input identifying a first design element group that includes two or more elements of the design;
receiving a second user input identifying a type of the first design element group;
generating a first object record that includes region data and type data, wherein the region data includes data describing a region of the first design element group in the design and the type data indicates the type of the first design element group;
generating a first training example that includes the first object record; and
storing the first training example.
Clause 2. The computer implemented method of clause 1, wherein the design is a raster format design that corresponds to a native format design.
Clause 3. The computer implemented method of clause 1, wherein the design is a native format design.
Clause 4. The computer implemented method of clause 3, further including:
generating a raster format version of the design; and
including the raster format version of the design or a link to the raster format version of the design in the first training example.
Clause 5. The computer implemented method of clause 3 or clause 4, wherein each design element is associated with an element bounding box, and wherein the method further includes calculating the region data for the first object record based on the bounding boxes of the two or more elements of the first design element group.
Clause 6. The computer implemented method of any one of clauses 3 to 5, further including generating membership data and associating the membership data with the first training example, wherein the membership data includes identifiers of the two or more elements of the first design element group.
Clause 7. The computer implemented method of any one of clauses 3 to 6, wherein the first user input includes two or more separate user inputs, each separate user input directly selecting one of the two or more elements of the first design element group.
Clause 8. The computer implemented method of any one of clauses 1 to 6, wherein the first user input is user that draws a first region on the design, the first region including the two or more elements of the first design element group.
Clause 9. The computer implemented method of any one of clauses 1 to 8, wherein the type of the first design element group is selected from a group including one or more of: a composite graphic type group; a content block type group; a chart type group; a graph type group; a table type group; and a diagram type group.
Clause 10. The computer implemented method of any one of clauses 1 to 9, further including updating the GUI to visually indicate that the two or more elements of the first design element group have been added to the first design element group.
Clause 11. The computer implemented method of any one of clauses 1 to 10, further including:
receiving a third user input identifying a second design element group that includes two or more elements of the design, the two or more elements included in the second design element group being different to the two or more elements included in the first design element group;
receiving a fourth user input identifying a type of the second design element group;
generating a second object record that includes region data and type data, wherein the region data includes data describing a region of the second design element group in the design and the type data indicates the type of the second design element group; and including the second object record in the first training example.

The following third set of numbered clauses describe additional, specific embodiments of the disclosure:
Clause 1. A computer implemented method including:
retrieving a first training example, wherein:
   the first training example includes a first design identifier that identifies a first design and first object data;
   the first object data includes a first object record in respect of a first element group that exists in the first design; and
   the first object record includes first region data that defines a region of the first element group in the first design; and
generating, by a computer processing unit, a second training example, wherein generating the second training example includes:
   determining a first adjustment;
   processing the first design in accordance with the first adjustment to generate a second design, wherein the second design includes a second element group, the second element group being an adjusted version of the first element group;
   generating a second object record in respect of the second element group;
   associating the second design with the second training example; and
   associating the second object record with the second training example.
Clause 2. The computer implemented method of clause 1, wherein determining the first adjustment includes determining a first adjustment type and a first adjustment parameter.
Clause 3. The computer implemented method of clause 1 or clause 2, wherein the generating the second object record includes:
determining second region data that defines a region of the second element group in the second design; and
including the second region data in the second object record.
Clause 4. The computer implemented method of clause 3, wherein the second region data is different to the first region data.
Clause 5. The computer implemented method of any one of clauses 1 to 4, wherein the first object data further includes type data that identifies a type of the first element group, and wherein the second object record is generated to include type data that identifies the type of the first element group.
Clause 6. The computer implemented method of any one of clauses 1 to 5, wherein:
the first object data includes a third object record that defines a third element group that exists in the first design;
the third object record includes third region data that defines a region of the third element group in the first design; and
generating the second training example further includes:
   determining that the second design includes a fourth element group that corresponds to the third element group; and
   in response to determining that the second design includes the fourth element group:
   generating a fourth object record in respect of the fourth element group; and
   including the fourth object record in the second training example.
Clause 7. The computer implemented method of any one of clauses 1 to 6, wherein the second design is generated as a raster format design and associating the second design with the second training example includes one or more of: including the second design in the second training example; including an identifier of a the second design in the second training example.
Clause 8. The computer implemented method of any one of clauses 1 to 6, wherein the first design is a native format design and the second design is generated as a native format design.
Clause 9. The computer implemented method of any one of clauses 1 to 8, wherein determining the first adjustment includes determining a rotation value and processing the first design to generate the second design includes rotating the first design by the rotation value.
Clause 10. The computer implemented method of any one of clauses 1 to 8, wherein determining the first adjustment includes determining a crop operation and processing the first design to generate the second design includes cropping the first design according to the crop operation.
Clause 11. The computer implemented method of any one of clauses 1 to 8, wherein determining the first adjustment includes determining a flip operation and processing the first design to generate the second design includes flipping the first design according to the flip operation.
Clause 12. The computer implemented method of clause 9, wherein determining the first adjustment includes determining one of: a horizontal flip operation; a vertical flip operation; a horizontal and vertical flip operation.
Clause 13. The computer implemented method of any one of clauses 1 to 8, wherein determining the first adjustment includes determining a colour adjustment operation and processing the first design to generate the second design includes performing the colour adjustment operation on the first design.
Clause 14. The computer implemented method of clause 11, wherein determining the first adjustment includes determining one of: a colour normalisation adjustment; a greyscale adjustment.
Clause 15. The computer implemented method of any one of clauses 1 to 8, wherein determining the first adjustment includes determining a scale value and processing the first design to generate the second design includes scaling the first design by the scale value.
Clause 16. The computer implemented method of any one of clauses 1 to 15, wherein the first training example is generated by a method according to any one of clauses 1 to 11 of the second clause set.

The following fourth set of numbered clauses describe additional, specific embodiments of the disclosure:
Clause 1. A computer implemented method including:
identifying a first design that includes a first placeholder element;
identifying a first data record, wherein the first data record defines a first element group that includes two or more design elements;
generating a second design based on the first design and the first element group, wherein generating the second design includes replacing the first placeholder element with a second element group, wherein the second element group is based on the first element group and includes design elements corresponding to each of the two or more design elements of the first element group;
generating a first object record, wherein the first object record includes region data that defines a region of the second element group in the second design; and
generating a training example that is associated with the second design and the first object record.
Clause 2. The computer implemented method of clause 1, wherein the first data record is associated with an existing training example.
Clause 3. The computer implemented method of clause 1 or clause 2, wherein the first data record includes a first element group type that defines a type of the first element group and wherein the first object record is generated to include type data that identifies the first element group type.
Clause 4. The computer implemented method of any one of clauses 1 to 3, wherein identifying the data record includes determining that the first element group is compatible with the first placeholder element.
Clause 5. The computer implemented method of clause 4, wherein determining that the first element group is compatible with the first placeholder element includes determining that an aspect ratio of the first element group is compatible with an aspect ratio of the placeholder element.
Clause 6. The computer implemented method of clause 4 or clause 5, wherein determining that the first element group is compatible with the first placeholder element includes determining that a size of the first element group is compatible with a size of the placeholder element.

Additional, specific embodiments of the disclosure include a computer processing system including:
a processing unit; and
non-transitory computer-readable media storing instructions which, when executed by the processing unit, cause the processing unit to perform: a method according to any one of clauses 1 to 12 of the first clause set; a method according to any one of clauses 1 to 11 of the second clause set; a method according to any one of clauses 1 to 16 of the third clause set; and/or a method according to any one of clauses 1 to 6 of the fourth clause set.

Additional, specific embodiments of the disclosure include non-transitory computer readable media storing instructions executable by a computer processing unit to cause the computer processing unit to perform: a method according to any one of clauses 1 to 12 of the first clause set; a method according to any one of clauses 1 to 11 of the second clause set; a method according to any one of clauses 1 to 16 of the third clause set; and/or a method according to any one of clauses 1 to 6 of the fourth clause set.

In certain embodiments described client application 132 (or an alternative application) operates to visually identify one or more design element groups that have been identified. Various techniques for visually identifying a design element group (and/or distinguishing between design element groups) are possible. By way of example, techniques for visually identifying and/or distinguishing design element groups may include using one or a combination of: shading colours; shading patterns; line colours; line weights; line styles; transparencies; icons; character annotations; animations; and/or other visual techniques.

The flowcharts illustrated in the figures and described above define operations in particular orders to explain various features. In some cases the operations described and illustrated may be able to be performed in a different order to that shown/described, one or more operations may be combined into a single operation, a single operation may be divided into multiple separate operations, and/or the function(s) achieved by one or more of the described/illustrated operations may be achieved by one or more alternative operations. Still further, the functionality/processing of a given flowchart operation could potentially be performed by (or in conjunction with) different applications running on the same or different computer processing systems.

In the above description, certain operations and features are explicitly described as being optional. This should not be interpreted as indicating that if an operation or feature is not explicitly described as being optional it should be considered essential. Even if an operation or feature is not explicitly described as being optional it may still be optional.

The present disclosure provides various user interface examples. It will be appreciated that alternative user interfaces are possible. Such alternative user interfaces may provide the same or similar user interface features to those described and/or illustrated in different ways, provide additional user interface features to those described and/or illustrated, or omit certain user interface features that have been described and/or illustrated.

In some instances the present disclosure and/or claims use the terms “first,” “second,” etc. to identify and distinguish between elements or features. When used in this way, these terms are not used in an ordinal sense and are not intended to imply any particular order. For example, a first feature could equally be referred to a second feature without departing from the scope of the described examples. Furthermore, when used to differentiate elements or features, a second feature could exist without a first feature or a second feature could occur before a first feature.

It will be understood that the embodiments disclosed and defined in this specification extend to alternative combinations of two or more of the individual features mentioned in or evident from the text or drawings. All of these different combinations constitute alternative embodiments of the present disclosure.

The present specification describes various embodiments with reference to numerous specific details that may vary from implementation to implementation. No limitation, element, property, feature, advantage or attribute that is not expressly recited in a claim should be considered as a required or essential feature. Accordingly, the specification and drawings are to be regarded in an illustrative rather than a restrictive sense.

1. A computer implemented method including:
accessing input design data in respect of an input design that includes a plurality of design elements;
processing, by a computer processing unit, the input design data to generate a raster design that corresponds to the input design;
processing the raster design to identify a first object in the raster design, wherein the first object corresponds to a first element group;
determining members of the first element group, wherein determining the members of the first element group includes:
determining that a first design element of the plurality of design elements is a member of the first element group based on a position of the first design element in the input design and a position of the first object in the raster design; and
determining that a second design element of the plurality of design elements is a member of the first element group based on a position of the second design element in the input design and a position of the first object in the raster design; and
generating a first element group record that includes an identifier of the first design element and an identifier of the second design element.

2. The computer implemented method of claim 1, wherein the method further includes determining a type of the first element group and including the type of the first element group in the first element group record.

3. The computer implemented method of claim 1, wherein:
the first object is associated with a first raster design region, the raster first raster region being a region of the first object in the design raster; and
determining that the first design element is a member of the first element group includes:
determining a first input design region, the first input design region being a region of the input design that corresponds to the first raster design region; and
determining that the first design element is a member of the first element group based on the position of the first design element and the first design region.

4. The computer implemented method of claim 3, wherein determining that the first design element is a member of the first element group includes determining that the first design element is located entirely within the first input design region.

5. The computer implemented method of claim 3, wherein determining that the first design element is a member of the first element group includes determining that the first design element is located partially within the first input design region.

6. The computer implemented method of claim 1, wherein processing the raster design to identify the first object in the raster design includes processing the raster design using a computer vision model that has been trained to identify objects corresponding to design element groups.

7. The computer implemented method of claim 3, wherein the computer vision model is a vision transformer model.

8. The computer implemented method of claim 1, wherein the raster design is a reduced size raster design and processing the input design data to generate the raster design includes one or both of: generating the raster design using a rasterization quality that is less than a maximum achievable rasterization quality; generating the raster design to have a resolution that is less than a resolution of the input design.

9. The computer implemented method of claim 1, wherein the method further includes determining bounding box data defining a bounding box of the first element group and including the bounding box data in the first element group record.

10. The computer implemented method of claim 9, wherein the bounding box data is based on a bounding box of the first design element and a bounding box of the second design element.

11. The computer implemented method of claim 1, further including:
causing the input design to be displayed in a graphical user interface (GUI); and
causing a visual indication that identifies the first element group to be displayed in the GUI.

12. A computer processing system including:
one or more processing units; and
non-transitory computer-readable media storing instructions which, when executed by the one or more processing units, cause the one or more processing units to perform a method including:
accessing input design data in respect of an input design that includes a plurality of design elements;
processing the input design data to generate a raster design that corresponds to the input design;
processing the raster design to identify a first object in the raster design, wherein the first object corresponds to a first element group;
determining members of the first element group, wherein determining the members of the first element group includes:
determining that a first design element of the plurality of design elements is a member of the first element group based on a position of the first design element in the input design and a position of the first object in the raster design; and
determining that a second design element of the plurality of design elements is a member of the first element group based on a position of the second design element in the input design and a position of the first object in the raster design; and
generating a first element group record that includes an identifier of the first design element and an identifier of the second design element.

13. The computer processing system of claim 12, wherein the method further includes determining a type of the first element group and including the type of the first element group in the first element group record.

14. The computer processing system of claim 12, wherein:
the first object is associated with a first raster design region, the raster first raster region being a region of the first object in the design raster; and
determining that the first design element is a member of the first element group includes:
determining a first input design region, the first input design region being a region of the input design that corresponds to the first raster design region; and
determining that the first design element is a member of the first element group based on the position of the first design element and the first design region.

15. The computer processing system of claim 12, wherein the raster design is a reduced size raster design and processing the input design data to generate the raster design includes one or both of: generating the raster design using a rasterization quality that is less than a maximum achievable rasterization quality; generating the raster design to have a resolution that is less than a resolution of the input design.

16. The computer processing system of claim 12, wherein the method further includes determining bounding box data defining a bounding box of the first element group and including the bounding box data in the first element group record.

17. The computer processing system of claim 12, wherein:
the computer processing system includes a display device; and
the method further includes:
displaying, on the display device, the input design to be displayed in a graphical user interface (GUI); and
causing a visual indication that identifies the first element group to be displayed in the GUI.

18. Non-transitory computer readable media storing instructions executable by one or more computer processing units to cause the one or more computer processing units to perform a method including:
accessing input design data in respect of an input design that includes a plurality of design elements;
processing the input design data to generate a raster design that corresponds to the input design;
processing the raster design to identify a first object in the raster design, wherein the first object corresponds to a first element group;
determining members of the first element group, wherein determining the members of the first element group includes:
determining that a first design element of the plurality of design elements is a member of the first element group based on a position of the first design element in the input design and a position of the first object in the raster design; and
determining that a second design element of the plurality of design elements is a member of the first element group based on a position of the second design element in the input design and a position of the first object in the raster design; and
generating a first element group record that includes an identifier of the first design element and an identifier of the second design element.

19. The non-transitory computer readable media of claim 18, wherein the method further includes determining a type of the first element group and including the type of the first element group in the first element group record.

20. The non-transitory computer readable media of claim 18, wherein:
the first object is associated with a first raster design region, the raster first raster region being a region of the first object in the design raster; and
determining that the first design element is a member of the first element group includes:
determining a first input design region, the first input design region being a region of the input design that corresponds to the first raster design region; and
determining that the first design element is a member of the first element group based on the position of the first design element and the first design region.
